(19) United States
(12) Patent Application Publication
(10) Pub. No.: US 2026/0094966 A1
(43) Pub. Date: Apr. 2, 2026

(54) MAGNETIC NANO-TRANSMITTER PLASMA WAVE ANTENNA

(71) Applicant: The Government of the United States of America, as represented by the Secretary of the Navy, Arlington, VA (US)

(72) Inventors: William Amatucci, Washington, DC (US); Matthew Finn, Washington, DC (US); Kyle Hrenyo, Washington, DC (US); Alexander Hyde, Washington, DC (US); Dennis Papadopoulos, Chevy Chase, MD (US)

(73) Assignee: he Government of the United States of America, as represented by the Secretary of the Navy, Arlington, VA (US)

(21) Appl. No.: 19/346,373

(22) Filed: Sep. 30, 2025

Related U.S. Application Data
(60) Provisional application No. 63/701,531, filed on Sep. 30, 2024.

(51) Int. Cl. H01Q 7/08; H01Q 17/00

(52) U.S. Cl. CPC H01Q 7/08; H01Q 17/002

(57) ABSTRACT

Systems and methods are provided for a compact, low-power, single-domain magnetic nanoparticle antenna that improves wave injection efficiency by more than 30 dB over conventional electric or magnetic dipoles, while reducing size, weight and power. This antenna allows in situ investigations to be performed with laboratory-like control to answer fundamental questions regarding nonlinear wave-particle interactions regarding the critical role that Electromagnetic Ion Cyclotron (EMIC) waves play in controlling radiation belt particle flux.

### CROSS REFERENCE TO RELATED APPLICATIONS

This application claims the benefit of U.S. Provisional Patent Application No. 63/701,531, filed on Sep. 30, 2024, which is incorporated by reference herein in its entirety.

### FEDERALLY SPONSORED RESEARCH AND DEVELOPMENT

The United States Government has ownership rights in this invention. Licensing inquiries may be directed to Office of Techno logy Transfer at US Naval Research Laboratory, Code 1004, Washington, DC 20375, USA; +1.202.767.7230; nrltechtran@us.navy.mil, referencing Navy Case Number 211825-US3.

### FIELD OF THE DISCLOSURE

This disclosure relates to antennas, including electromagnetic wave antennas.

### BACKGROUND

Naturally occurring and man-made space weather events can increase the flux of high energy protons and electrons trapped in the Earth's radiation belts. An unexpected sharp increase in the flux of trapped high-energy particle populations poses a significant threat to the entire Low Earth Orbit (LEO) satellite fleet by delivering an expected lifetime's dose of radiation in a short period of time.

In the typical natural conditions, the energetic particle fluxes are controlled by resonant interactions of the particles with electromagnetic plasma waves, such as whistler mode waves and electromagnetic ion cyclotron (EMIC) waves. These wave-particle interactions cause the deflection of the trapped particle velocity vector, lowering its reflection height to altitudes where collisions with the increasing neutral particle density in the Earth's upper atmosphere lead to recombination and removal of scattered trapped particles.

A man-made space weather event, such as the detonation of a high-altitude nuclear weapon, can create long-lived artificial radiation belts with particle fluxes that are orders of magnitude greater than the natural belts. In such an event, remediation of the injected particles must occur on a time scale faster than the time it takes for satellites to acquire dangerous levels of radiation dose in order to avoid damage to solar panels and loss of sensitive satellite electronics that in today's Starlink type satellites are mainly Commercially-off-the Shelf (COTS).

### BRIEF DESCRIPTION OF THE DRAWINGS/FIGURES

The accompanying drawings, which are incorporated in and constitute part of the specification, illustrate embodiments of the disclosure and, together with the general description given above and the detailed descriptions of embodiments given below, serve to explain the principles of the present disclosure. In the drawings:

FIG. 1A is a diagram showing a Rotating Magnetic Field (RMF) antenna in accordance with an embodiment of the present disclosure;

FIG. 1B shows diagrams of a magnetic field structure of 1=1 SAW with OAM on a plane perpendicular to the ambient magnetic field at a distance 2.88 m from the RFM antenna in accordance with an embodiment of the present disclosure;

FIG. 1C shows an exemplary laboratory experiment in accordance with an embodiment of the present disclosure;

FIG. 1D shows a magnetic structure in accordance with an embodiment of the present disclosure;

FIG. 2A is a diagram showing an air-core coil in accordance with an embodiment of the present disclosure;

FIG. 2B is a diagram showing a high-u core coil in accordance with an embodiment of the present disclosure;

FIG. 2C is a diagram showing an example of a whistler wave launched with a ferrite-core antenna showing increase in wave amplitude proportional to effective u of core in accordance with an embodiment of the present disclosure;

FIG. 2D is a diagram showing a schematic illustration of the energy of Single Domain Nanoparticles (SDN) with uniaxial anisotropy as a function of magnetization direction in accordance with an embodiment of the present disclosure;

FIG. 2E is a diagram showing magnetization curves for SDNs as a function of α=μB/k_{B}T in accordance with an embodiment of the present disclosure;

FIG. 3A is an illustration showing a notional designs for a crossed dipole configuration of MNT elements in accordance with an embodiment of the present disclosure;

FIG. 3B is an image showing the notional designs for a linear array of MNT elements in accordance with an embodiment of the present disclosure;

FIG. 3C is an image showing the notional designs for a circular antenna with MNT elements located uniformly along the circumference of a circular ring with radius a in accordance with an embodiment of the present disclosure;

FIG. 3D shows images for the magnetic structure for modes 1=1-3 on a plane perpendicular to the ambient magnetic field at 100 meters from the MANTA with 6 MNT elements in accordance with an embodiment of the present disclosure;

FIG. 3E shows a schematic of an 1=2 mode with overlays of one centered and one displaced gyro-orbit of a relativistic electron in accordance with an embodiment of the present disclosure;

FIG. 3F is a diagram showing the minimum electron energy for 30 Hz planar (1=0) EMIC waves as a function of L in accordance with an embodiment of the present disclosure;

FIG. 3G is a diagram showing the minimum electron energy cs OAM mode number for L=1.2, f=30 Hz in accordance with an embodiment of the present disclosure;

FIG. 4A shows a design for a notational Magnetic Nano-Transmitter Plasma Wave Antenna (MANTA) array in accordance with an embodiment of the present disclosure;

FIG. 4B is a diagram showing how a MANTA launches an electromagnetic ion cyclotron (EMIC) wave from space platform emissions in accordance with an embodiment of the present disclosure;

FIG. 5 is a diagram showing exemplary observations from the magnetosphere in accordance with an embodiment of the present disclosure;

FIG. 6 is a diagram showing a ferrite loop antenna (FLA) and a ceramic core antenna in accordance with an embodiment of the present disclosure;

FIG. 7A shows images of 20 nm FeCo nanoparticles 702 and FeCo nanoparticles suspended in a paraffin matrix 704 in accordance with an embodiment of the present disclosure;

FIG. 7B is a diagram showing a comparison of the hysteresis curves for FeCo nanoparticles and commercially available ferrite material (Amidon Corp R61) in accordance with an embodiment of the present disclosure;

FIG. 7C shows diagrams illustrating the variation of the magnetization of Fe—Co and the anisotropy constant as a function of the x=Fe/Co ratio in accordance with an embodiment of the present disclosure;

FIG. 7D shows diagrams illustrating the variation of saturation magnetization, Tc, magnetocrystalline anisotropy, K1, and magnetostriction, λ, in FeCo alloys in accordance with an embodiment of the present disclosure;

FIG. 8 shows a simulation of very low frequency (VLF) wave generation with a FLA array in accordance with an embodiment of the present disclosure;

FIG. 9A is a diagram showing an exemplary linear array configuration with two antenna cores in accordance with an embodiment of the present disclosure;

FIG. 9B is a diagram showing an exemplary linear array configuration with 10 antenna cores in accordance with an embodiment of the present disclosure;

FIG. 9C is a diagram showing an exemplary linear array configuration with 4 antenna cores in accordance with an embodiment of the present disclosure;

FIG. 10 is a diagram showing an exemplary circular array configuration in accordance with an embodiment of the present disclosure;

FIG. 11 is a diagram showing another exemplary circular array configuration in accordance with an embodiment of the present disclosure;

FIG. 12 is a diagram showing another exemplary circular array configuration in accordance with an embodiment of the present disclosure;

FIG. 13 is a diagram showing another exemplary circular array configuration of satellites with phased MANTA transmitting antennas in accordance with an embodiment of the present disclosure;

FIG. 14 is a diagram showing a constellation of satellites, each fielding a manta array, in accordance with an embodiment of the present disclosure; and

FIG. 15 is a diagram showing exemplary very low frequency (VLF) communications via satellite constellations of MANTA arrays in accordance with an embodiment of the present disclosure.

Features and advantages of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

In the following description, numerous specific details are set forth to provide a thorough understanding of the disclosure. However, it will be apparent to those skilled in the art that the disclosure, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring aspects of the disclosure.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to understand that such description(s) can affect such feature, structure, or characteristic in connection with other embodiments whether or not explicitly described.

### 1. Overview

Embodiments of the present disclosure provide a compact, high-efficiency, low-frequency plasma wave transmitting antenna to launch EMIC waves with high amplitude and Orbital Angular Momentum (OAM) on demand. EMIC waves with OAM are unique and allow strong non-resonant interaction with relativistic electrons in the inner radiation belt in general and at L-Shell values between 1.1 and 1.3 location of more than 10,000 Starlink satellites.

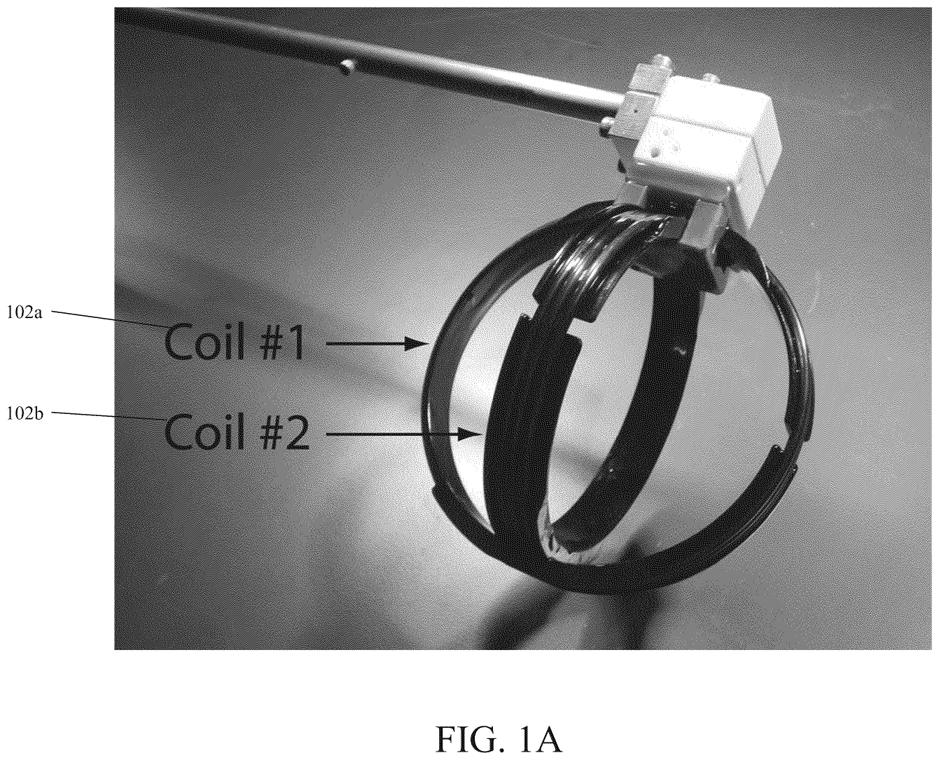

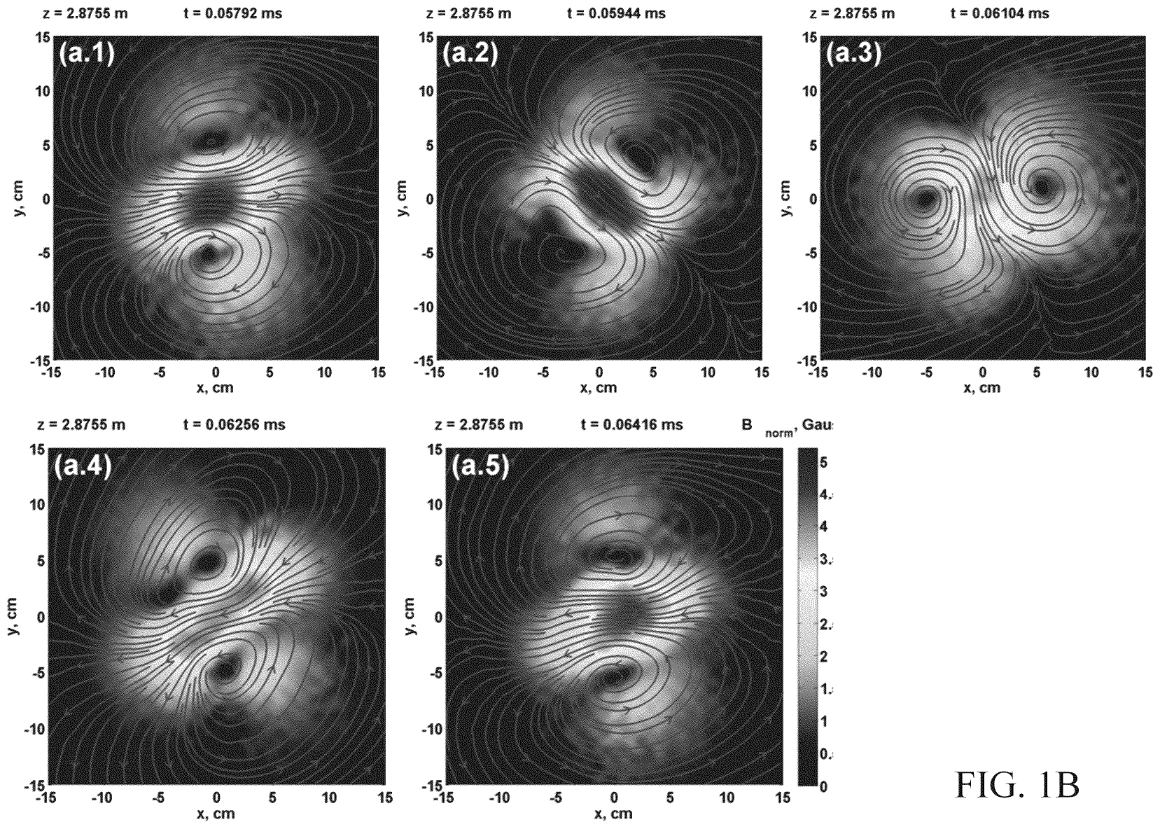

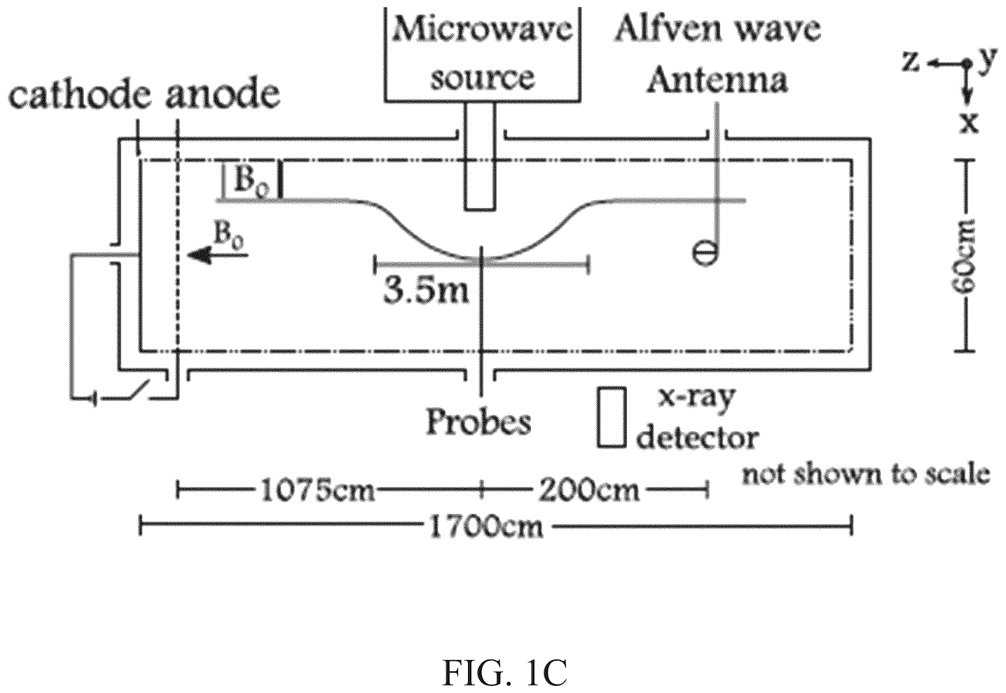

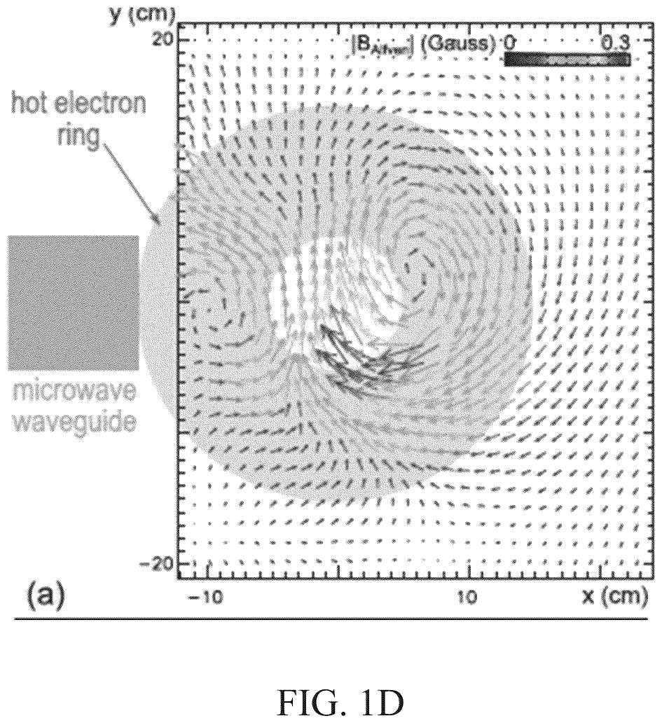

Recent observations indicate that short EMIC wave packets lead to scattering and precipitation of relativistic electrons at energies much below expected theoretical minimum energy threshold. FIG. 1A is a diagram showing a Rotating Magnetic Field (RMF) antenna in accordance with an embodiment of the present disclosure. In FIG. 1A, the RMF antenna has two coils 102 (e.g., loops) perpendicular to each and to the ambient magnetic field with a phase difference π/2 generated a rotating Shear Alfven Wave (SAW) with OAM whose rotation direction could be controlled. FIG. 1B shows diagrams of a magnetic field structure of 1=1 SAW with OAM on a plane perpendicular to the ambient magnetic field at a distance 2.88 m from the RFM antenna in accordance with an embodiment of the present disclosure.

FIG. 1C shows an exemplary laboratory experiment in accordance with an embodiment of the present disclosure. FIG. 1C shows a magnetic mirror field configuration, along with the location of the microwave sources, SAW antenna and probes. FIG. 1D shows a magnetic structure in accordance with an embodiment of the present disclosure. FIG. 1D shows a magnetic structure of the 1=1, SAW with OAM injected measured in a plane in the center of the mirror. FIG. 1D shows that when such an antenna was placed in a mirror magnetic field in which MeV electrons were injected, it resulted in local break-down of their adiabatic invariant, resulting in pitch angle scattering and loss of the confined electrons. Using a similar cross field loop configuration in space is extremely inefficient due to its low radiation resistance.

To increase the magnetic moment of loop antennas previously considered for space applications, increasing the diameter of the current loop may be considered. Without considering the practical difficulties of launching a large-diameter magnetic loop, at the low oxygen ion cyclotron frequency range in the ionosphere, the radiation resistance of even a 15-m diameter loop is ˜10⁻⁵Ω. Thus, a current of ˜315 A is required to inject ˜1 W of power with an efficiency less than 0.1%. Stacking many loops to increase the radiation resistance results in large increases in inductance, requiring higher voltages and risking electrical breakdown in the ionospheric environment.

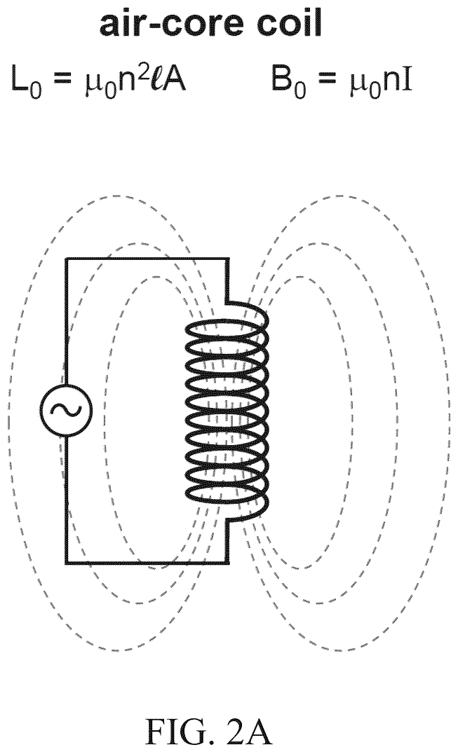

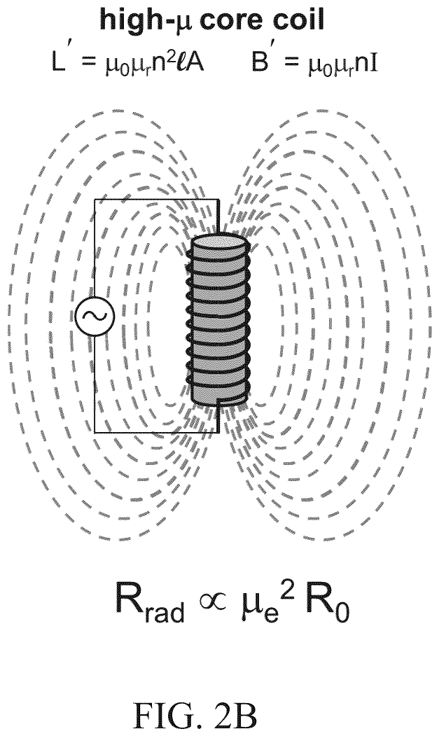

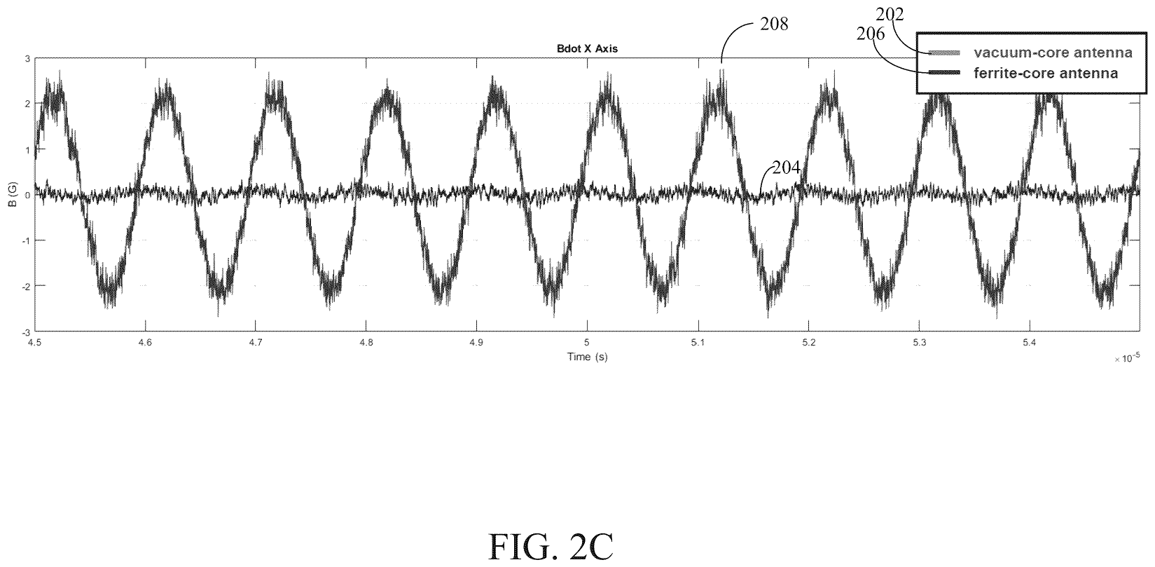

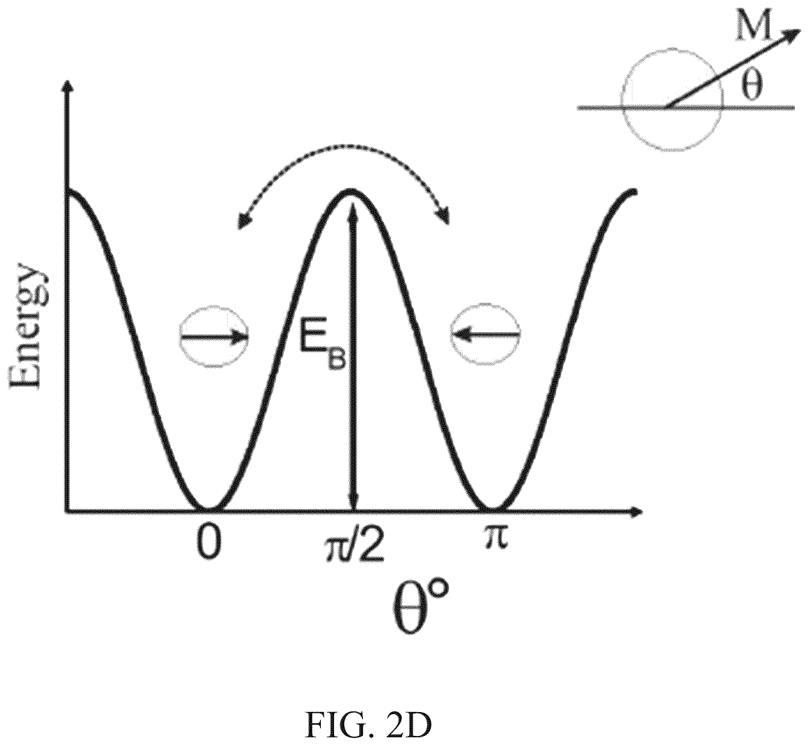

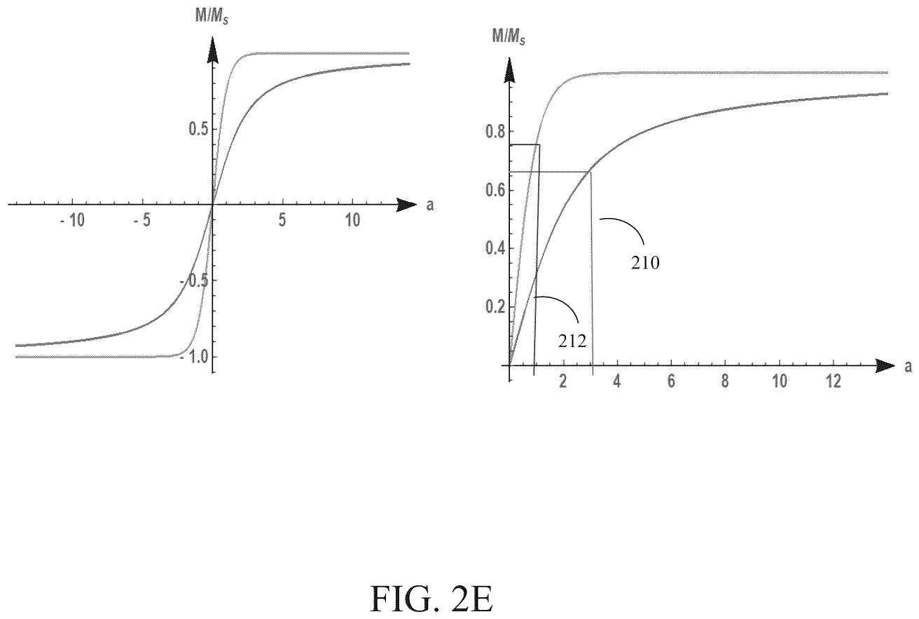

Embodiments of the present disclosure provide a remediation technique using a magnetic nanoparticle antenna (MNT), which can inject plasma waves with amplitudes in excess of 30 dB greater than conventional magnetic loop antennas. In an embodiment, the remediation technique disclosed here has two components: The first one is an MNT element that replaces the loops mentioned previously illustrated in FIG. 1A. FIG. 2A is a diagram showing an air-core coil in accordance with an embodiment of the present disclosure. FIG. 2B is a diagram showing a high-μ core coil in accordance with an embodiment of the present disclosure. FIG. 2B illustrates the dramatic improvement in magnetic loop antenna efficiency with the addition of a high permeability core. A low-loss, high-permeability material within a multi-turn magnetic loop antenna increases the MNT radiation resistance by a factor of μₑ₂, dramatically improving the coupling to the plasma.

FIG. 2C is a diagram showing an example of a whistler wave launched with a ferrite-core antenna showing increase in wave amplitude proportional to effective u of core in accordance with an embodiment of the present disclosure. FIG. 2C shows the comparison between a vacuum-core antenna 202 with a ferrite-core antenna 206. The dramatic increase in wave amplitude observed in the plasma for equal antenna driving currents is due to the effective u of the ferrite (μₑ˜20). In an embodiment, while the ferrite core generates significant amplification as it will be disclosed further, a laminated Hyperco (a Fe—Co—V soft alloy) core has saturation magnetization and susceptibility more than an order of magnitude higher than ferrite.

A significant drawback of Hyperco is demagnetization and hysteresis losses, drawbacks shared with all magnetic isotropic core materials. To minimize hysteresis losses and demagnetization packing constraints embodiments of the present disclosure enable the use of 10-20 nm, Co50Fe50 Single Domain Nanoparticles (SDN) with uniaxial anisotropy along the easy axis inserted in a non-conducting core.

FIG. 2D is a diagram showing a schematic illustration of the energy of an Single Domain Nanoparticles (SDN) with uniaxial anisotropy as a function of magnetization direction in accordance with an embodiment of the present disclosure. In FIG. 2D, E_{B} is the energy barrier needed for the rotation of the magnetization, and θ is the angle between the magnetization M and the easy axis.

FIG. 2E is a diagram showing magnetization curves for SDNs as a function of α=μB/k_{B}T in accordance with an embodiment of the present disclosure. In FIG. 2E, notation 210 represents spatially randomly oriented easy axes with respect to the applied magnetic field, and notation 212 represents easy axes aligned with respect to the magnetic field. Notice that while magnetically isotropic core materials have a Langevin response to an applied magnetic field B, uniaxial core materials follow Brillouin two state response (up or down) resulting in extremely large susceptibility (slope of the curve). Furthermore, the demagnetization is substantially reduced since the anisotropic material resists rotation.

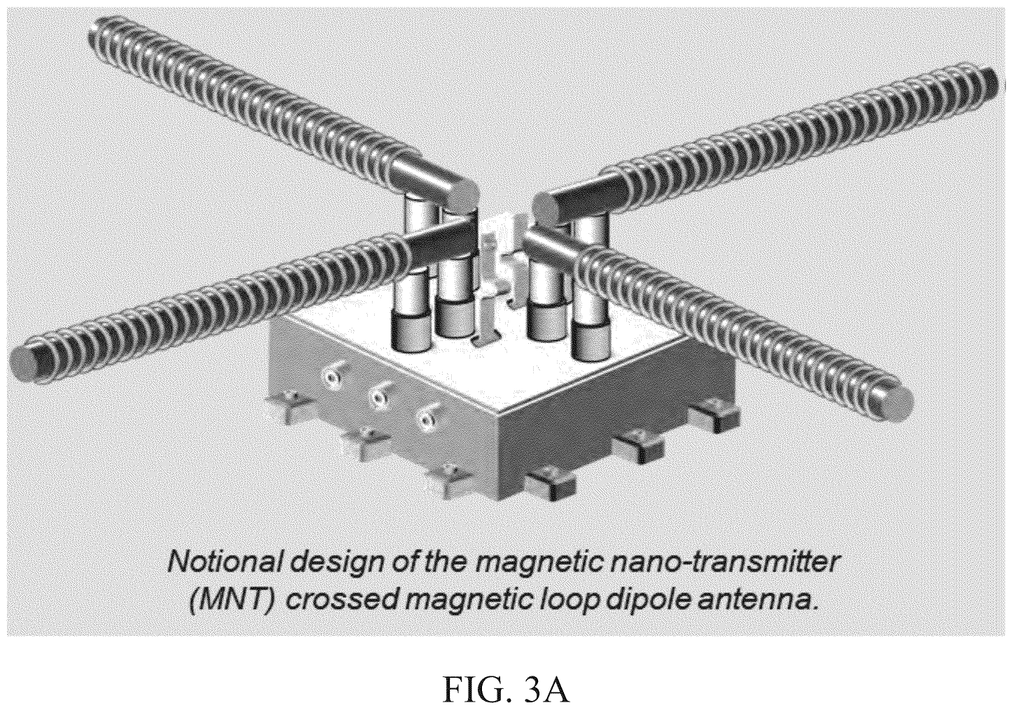

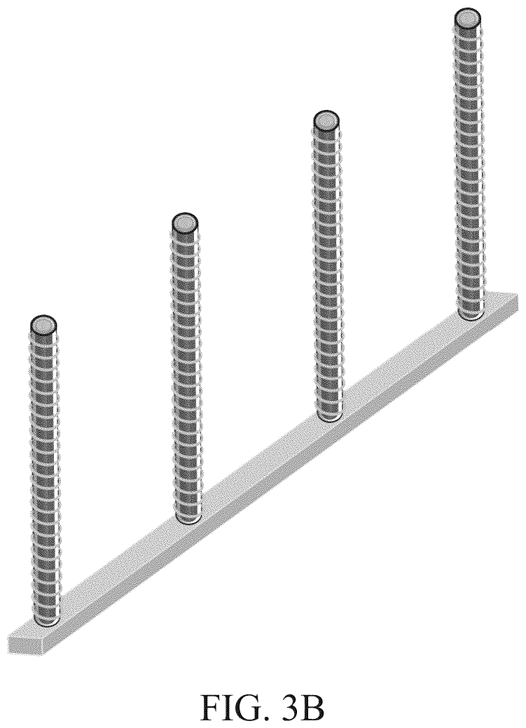

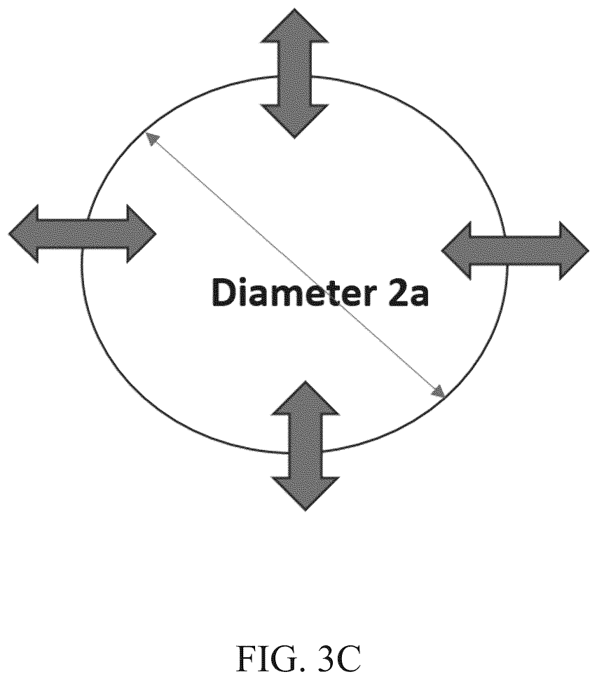

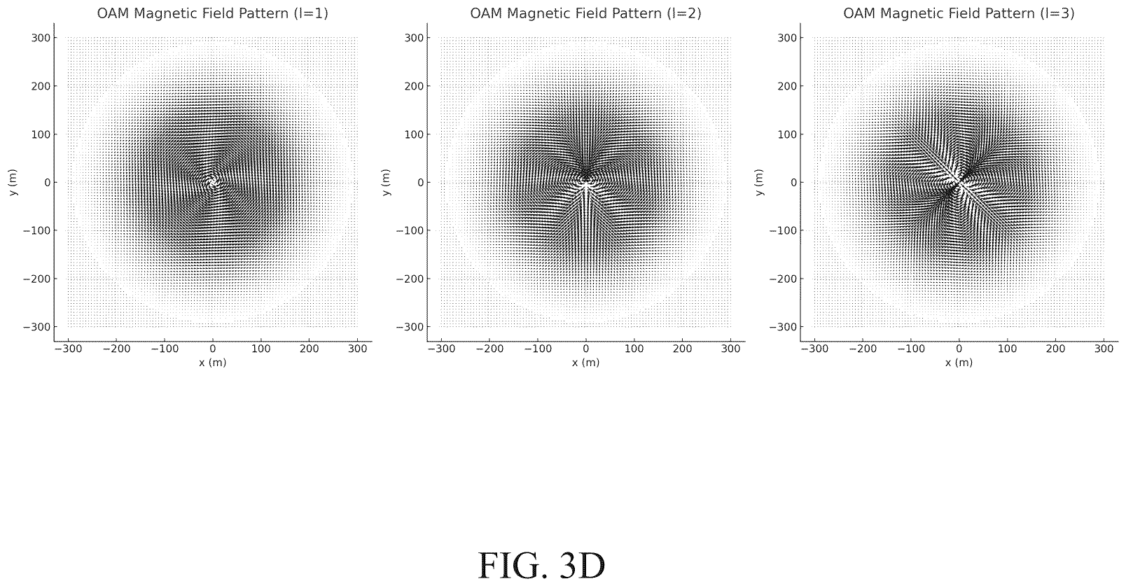

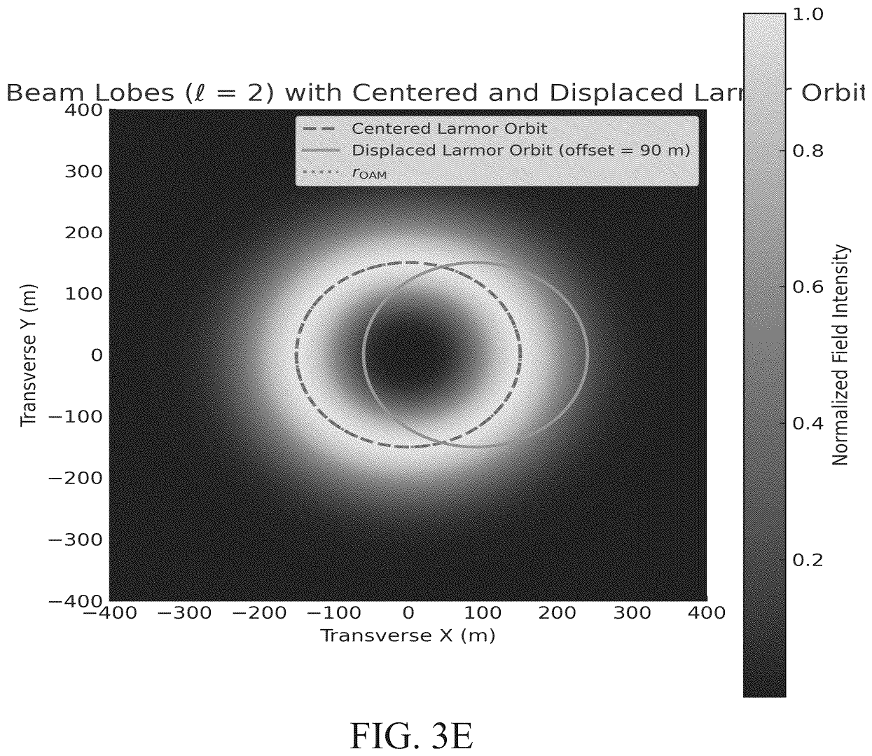

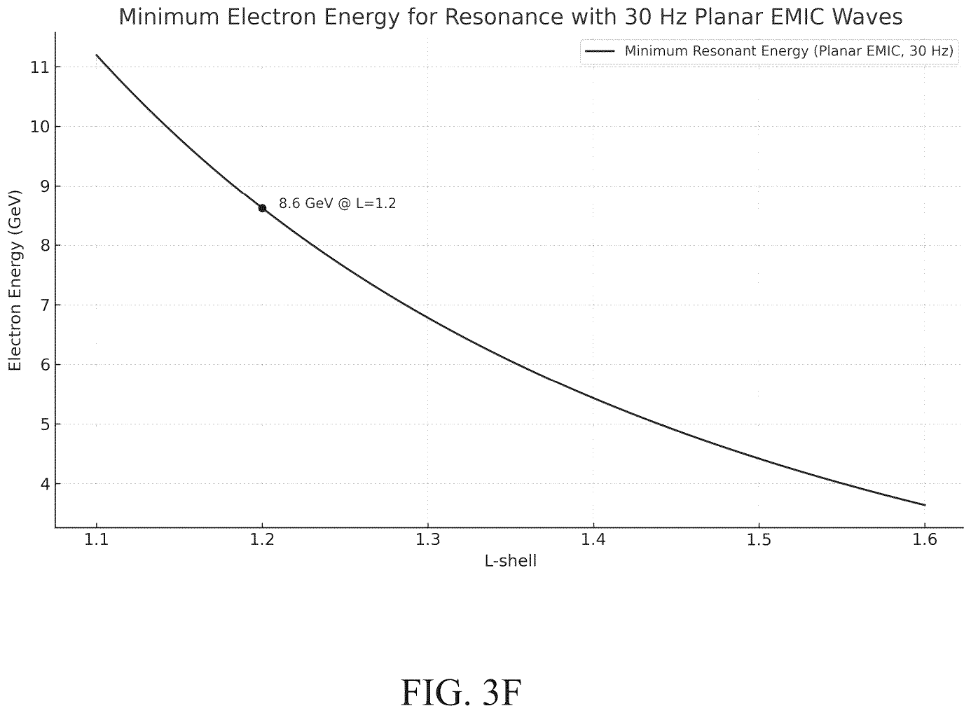

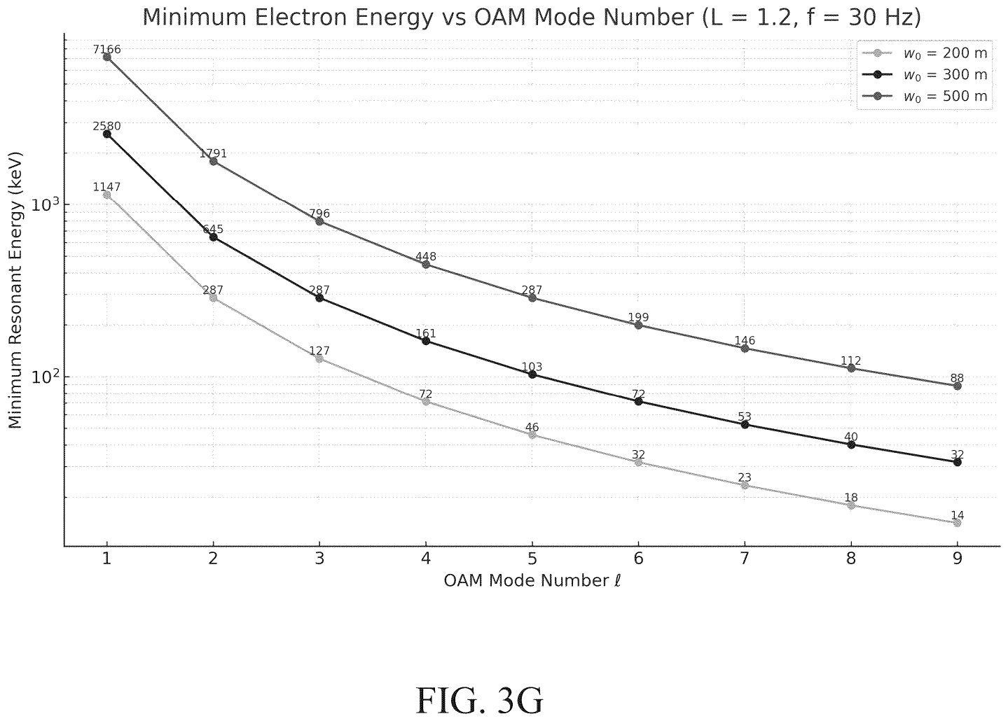

In an embodiment, the second component of the disclosure describes MNT Arrays (MANTA). MANTA configurations can be used to generate magnetic configurations with OAM. FIG. 3A is an image showing the notional designs for a crossed dipole configuration of MNT elements in accordance with an embodiment of the present disclosure. FIG. 3B is an image showing the notional designs for a linear array of MNT elements in accordance with an embodiment of the present disclosure. FIG. 3C is an image showing the notional designs for a circular antenna with MNT elements located uniformly along the circumference of a circular ring with radius a in accordance with an embodiment of the present disclosure.

In an embodiment, in the crossed-dipole configuration of FIG. 3A, EMIC waves are launched by driving the orthogonal pair of antennas 90-degrees out of phase in the left-hand circular polarization direction. In an embodiment, in the linear array configuration of FIG. 3B, array elements are driven with phase differences specific to launching EMIC waves with parallel wavelength corresponding to the array configuration and element phasing and intensity dependent on the number of MNT elements. In an embodiment, in the circular configuration of FIG. 3C, the array elements are driven sequentially, phased to radiate at the desired frequency and with the desired polarization.

In an embodiment an important MANTA configuration relies on variations of the circular configuration shown in FIG. 3C but with total N elements distributed isotopically each with phase

$${ϕ}_{n} = \frac{2 π ln}{N} ,$$

where n refers to nₜₕ MINT element and 1 is the azimuthal mode number. FIG. 3D shows images for the magnetic structure for modes l=1-3 on a plane perpendicular to the ambient magnetic field at 100 meters from the MANTA with 6 MNT elements in accordance with an embodiment of the present disclosure. One can see that OAM with different 1 numbers generate different magnetic and associated electric field structures.

FIG. 3E shows a schematic of an l=2 mode with overlays of one centered and one displaced gyro-orbit of a relativistic electron in accordance with an embodiment of the present disclosure. For MeV electrons and with large Larmor gyro-radii, OAM modes allow nonlocal coupling between the EMIC waves and the gyromotion of relativistic electrons, shown schematically in FIG. 3E, leading to break of their adiabatic invariance and enhanced pitch angle scattering. The modified resonance

$$ω - {k}_{i i} {v}_{i i} - l {ω}_{ϕ} = ∓ \frac{n {Ω}_{e}}{γ} , {ω}_{ϕ} \approx \frac{c}{{ρ}_{e}} ;$$

where ρₑ is the electron gyro-radius. Since ω,kᵢᵢvᵢᵢ<<Ωₑ the modified broadened condition becomes lc/ρₑ≈Ωₑ/γ. Furthermore, by coherently combining many elements we can achieve a very high magnetic moment at the chosen EMIC frequency.

Another critical property of EMIC waves with OAM is the fact that when they are injected into geomagnetic cells L=1.1-1.3, where more than 10000 Starlink satellites reside, the required minimum resonant energy to interact with relativistic electrons reduces to less than 0.5 Mev from several tens of GeV for planar (l=0) EMIC waves. FIG. 3F is a diagram showing the minimum electron energy for 30 Hz planar (l=0) EMIC waves as a function of L in accordance with an embodiment of the present disclosure. This compared to the particular example for L=1.2, demonstrates that in addition to enormous reduction of the minimum energy in the relevant energy region (0.5-3 MeV), the circular MANTA antenna has unparalleled flexibility. FIG. 3G is a diagram showing the minimum electron energy cs OAM mode number for L=1.2, f=30 Hz in accordance with an embodiment of the present disclosure.

A remediation technique enabled by embodiments of the present disclosure is made possible by the disclosed magnetic nanoparticle antenna (MNTA), which can inject EMIC waves with OAM and in excess of 30 dB greater than conventional magnetic loop antennas. The ability to drive large amplitude EMIC waves presents the opportunity to exploit nonlinear plasma processes leading to Triggered EMIC (TEMIC) emissions, which leverages the energy of the trapped energetic particle populations themselves to provide another ˜30 dB amplification of the injected waves. These triggered emissions provide the scattering required for remediation of the trapped radiation belt particles.

A MANTA in accordance with an embodiment of the present disclosure can provide the necessary tool for carrying out experimentation in space with laboratory-like precision to examine the critical role that EMIC and TEMIC waves play in controlling the flux of radiation belt particles through nonlinear wave-particle interactions. Triggered emissions can require a threshold amplitude of the original triggering wave in addition to the presence of anisotropic particle distributions that provide the energy for amplification.

In an embodiment, the triggered wave is amplified by several tens of dB, has a rising frequency, and includes a number of subpackets. In an embodiment, a non-linear interaction between the triggered wave and trapped energetic particles is repeated many times during the triggering period, while a substantial number of trapped particles are precipitated through scattering from nonlinear structures generated by wave trapping within the rising-tone emissions. Such interactions control the flux of radiation belt particles in the natural environment. Understanding and exploiting the underlying physics is important in developing active control of natural or artificially enhanced populations of trapped energetic particles that pose a threat to LEO satellites.

Under natural conditions in the Earth's outer radiation belts, EMIC waves arise spontaneously, driven by an anisotropic instability of trapped energetic particles. However, in the inner radiation belt region where the bulk of the LEO satellite fleet operates, EMIC waves do not typically arise spontaneously due to the low flux of anisotropic particle distributions with energy in the 1-100 keV range. The absence of a source for spontaneously generated EMIC waves in the inner magnetosphere represents a major reason that an antenna such as the MNTA is required. For understanding the physics of radiation belt remediation (RBR), this created a unique opportunity to exploit an otherwise naturally quiet portion of the plasma wave spectrum to investigate the nonlinear processes leading to triggered emissions are energetic particle precipitation. The ability to control the frequency and amplitude and OAM of the only source of EMIC waves will greatly clarify the cause and effects that follow in a natural low-noise environment.

Embodiments of the present disclosure provide a compact, efficient, low-frequency transmitting antenna for the controlled, direct interaction with energetic radiation belt particles trapped within Earth's magnetic field, as well as other low-frequency electromagnetic wave transmission applications. In an embodiment, a compact, low-power magnetic loop antenna is formed from a solenoidal wire coil wrapped over a magnetic nanoparticle core. Such an antenna can take advantage of the natural high gain due to guidance of EMIC waves (˜1-100 Hz) by the ambient magnetic field to a cone smaller than 1° along the magnetic field lines, resulting in EMIC wave amplitudes larger than 0.1-1 nT for radiated antenna powers of approximately 1-5 W.

At this injection power the wave amplitude exceeds the TEMIC threshold at distances of more than one hundred kilometers. One configuration of MNT antenna elements consists of a crossed dipole pair driven 90-degrees out of phase to launch left-hand circularly polarized EMIC waves from a space platform. In an embodiment, each MNT element includes a cylindrical magnetic nanoparticle core with a tightly wound axial wire coil driven by a matched AC circuit.

In an embodiment, another MNT antenna configuration includes a linear array of MNT elements with separation distances and phase differences chosen to drive a particular EMIC wavelength transverse and parallel to the ambient magnetic field.

In an embodiment, a third antenna configuration includes a circular antenna with MNT elements located uniformly spaced along the circumference and phased to radiate at the desired frequency. The MNT elements can be oriented either perpendicular or parallel to the ambient magnetic field.

In an embodiment, the MNT arrays generate Rotating Magnetic Fields (RMF) in the plasma. In the transverse plane, the magnetic field has a rotating two-vortex structure with the rotating vortices corresponding to field-aligned currents. Depending on the polarization of the source, the magnetic field at the center rotates either clockwise (cw) or counterclockwise (ccw). The combination of phase rotation and field aligned propagation results in spiraling phase surfaces like helicons. A unique property of the MNT generated waves is that they possess Orbital Angular Momentum (OAM) driven by the group velocity. This is in addition to the Spin Angular Momentum (SAM) associated with phase velocity.

Key properties of the MNT arrays in accordance with embodiments of the present disclosure include the following. For example, they generate OAM in addition to SAM. While SAM creates radiation pressure on interacting particles, the OAM exerts torque that alters the field rotation. The OAM drives the resonant interaction of trapped energetic radiation belt particles with the rotating field when lω_{φ}≈Ωₑ, even if the traditional ω−k·v_{∥}=nΩ cyclotron resonance is not satisfied. The wave's phase Exp[ilφ] rotates with respect to the electron's gyro or drift motion. Resonance occurs when the wave phase is stationary in the electron frame. This allows for continuous torque like interaction between the wave OAM and the electron orbital motion. This leads to: (a) Magnetic moment breakdown—due to strong transverse field gradients in structured modes and, (b) Pitch angle diffusion; changes in vᵢᵢ/v⊥—leading. to precipitation. In fact, it becomes the dominant pitch-angle scattering process for RBR applications since the traditional resonance conditions cannot be satisfied due to the large mass difference of the proton driven EMIC waves with electrons. In an embodiment, although radial propagation occurs, the antenna determines the perpendicular phase velocity and amplitude profile, while the highly aligned group velocity prevents the radial energy spread. In an embodiment, phased MNT arrays allow control of the radial wavelength and determine the effective loop antenna size that controls the coupling efficiency of the antenna to the ELF/VLF plasma mode. In an embodiment, OAM reduces the required minimum resonant energy of EMIC waves injected in geomagnetic shells L=1.1-1.3 (location of Starlink type satellites) reduces to above 0.5 MeV, while planar injection without OAM (l=0) has minimum energy that exceeds several GeV.

In an embodiment, if scaled to larger dimensions, the MNT antenna concept has additional applications as a low frequency transmitting antenna. Such applications include undersea communications.

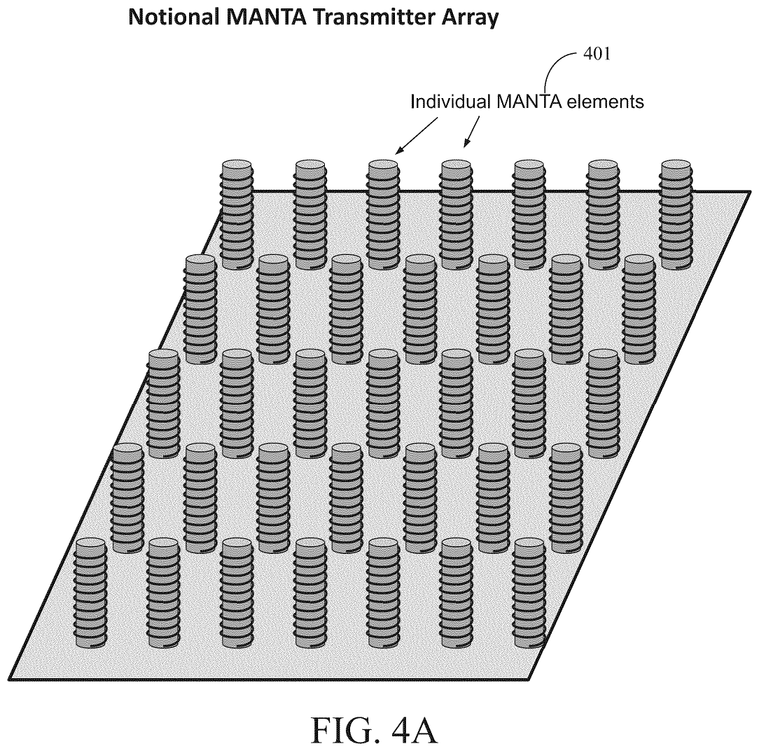

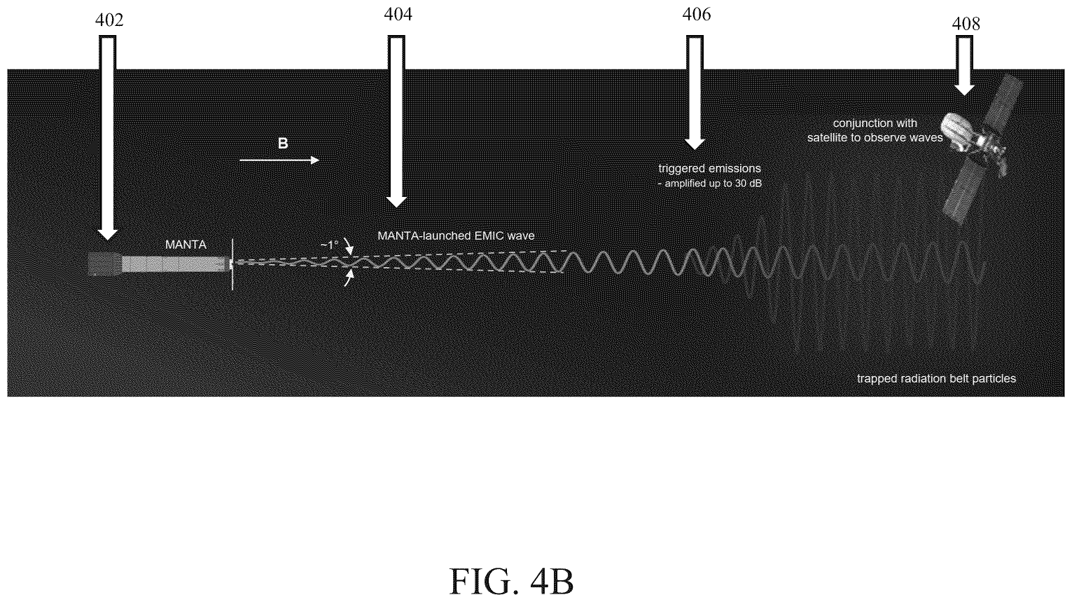

FIG. 3A is an illustration showing a notional designs for a crossed dipole configuration of MNT elements in accordance with an embodiment of the present disclosure. As shown in FIG. 3A, the crossed dipole configuration of MNT elements of FIG. 3A has 4 MNT elements attached to a base structure with an alternating current (AC) circuit that drives the elements. As shown in FIG. 3A, the 4 MNT elements are coplanar with each other and are arranged at 90 degree angles with respect to each other. In an embodiment, the crossed dipole configuration of FIG. 3A is a single unit cell in a MNT array. FIG. 4A shows a design for a notational Magnetic Nano-Transmitter Plasma Wave Antenna (MANTA) array in accordance with an embodiment of the present disclosure. As shown in FIG. 4A the MANTA array has a plurality of elements 401.

MNT elements in accordance with embodiments of the present disclosure can be implemented in a variety of ways, such as a linear array of MNT elements or as a circular antenna with MNT elements located uniformly along the circumference of a circular ring. In the crossed-dipole configuration of FIG. 3A, EMIC waves can be launched by driving the orthogonal pair of antennas 90-degrees out of phase in the left-hand circular polarization direction. In a linear array configuration, array elements can be driven with phase differences specific to launching EMIC waves with parallel wavelength corresponding to the array configuration and element phasing and intensity dependent on the number of MNT elements. In a circular configuration, the array elements can be driven sequentially, phased to radiate at the desired frequency and with the desired polarization.

FIG. 4B is a diagram showing how a MANTA launches an electromagnetic ion cyclotron (EMIC) wave from space platform emissions in accordance with an embodiment of the present disclosure. In FIG. 4B, a MANTA 402 launches an EMIC wave 404, and the triggered emissions are amplified up to 30 dB 406 and observed by a satellite 408.

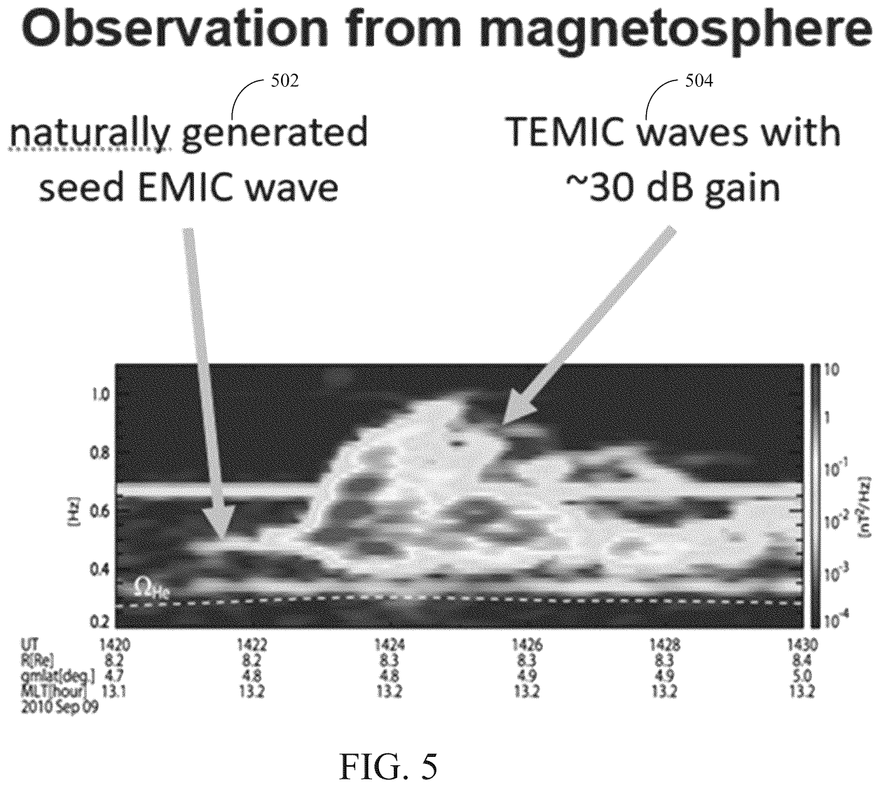

FIG. 5 is a diagram showing exemplary observations from the magnetosphere in accordance with an embodiment of the present disclosure. FIG. 5 shows a naturally generated seed EMIC wave 502 and Triggered EMIC (TEMIC) waves 504 with ˜30 dB gain.

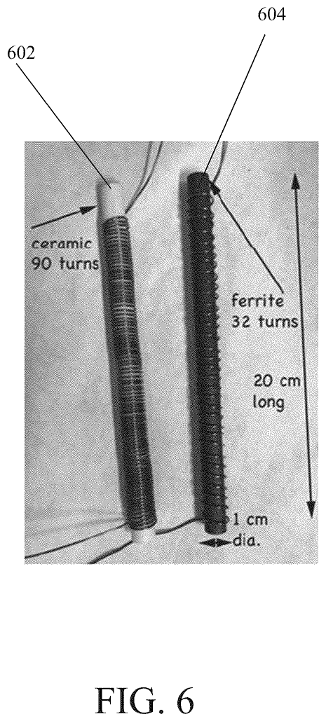

FIG. 6 is a diagram showing a ferrite loop antenna (FLA) 604 and a ceramic core antenna 602 in accordance with an embodiment of the present disclosure.

FIG. 2C is a diagram showing an example of a whistler wave launched with a ferrite-core antenna showing increase in wave amplitude proportional to effective u of core in accordance with an embodiment of the present disclosure. In FIG. 2C, vacuum-core antenna 202 corresponds to plot 204, and ferrite-core antenna 206 corresponds to plot 208 in accordance with an embodiment of the present disclosure. FIG. 6C shows the comparison between a vacuum-core antenna 202 with a ferrite-core antenna 206. The dramatic increase in wave amplitude observed in the plasma for equal antenna driving currents is due to the effective u of the ferrite (μₑ˜20).

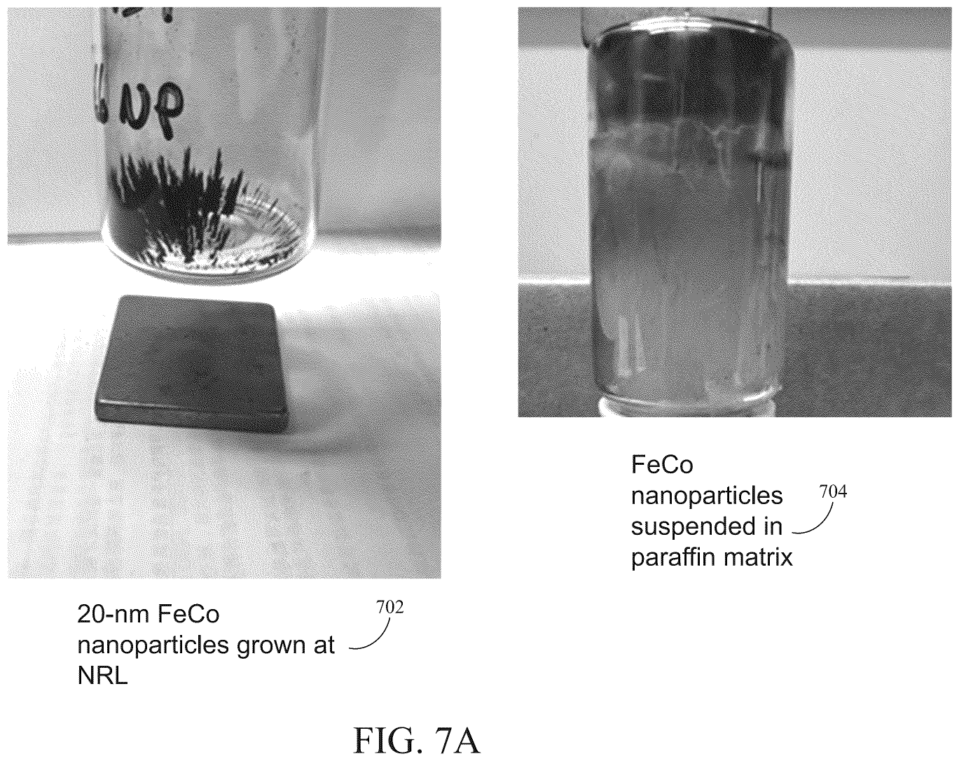

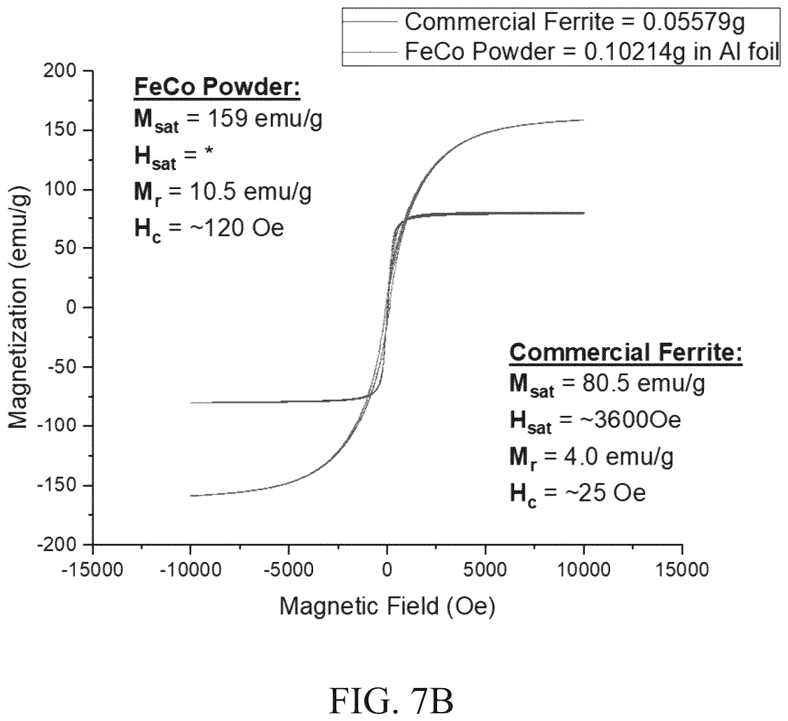

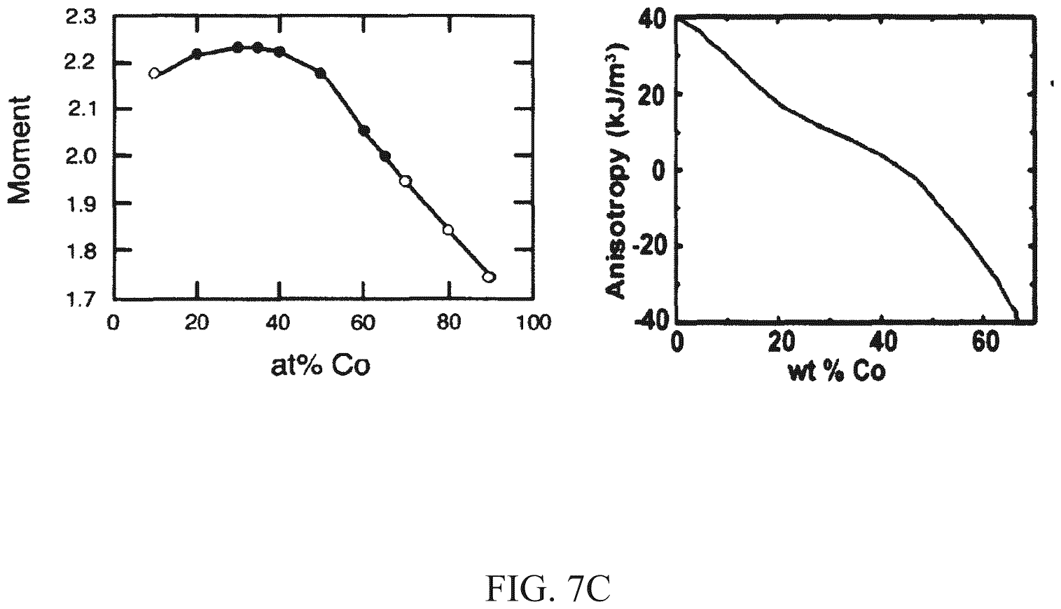

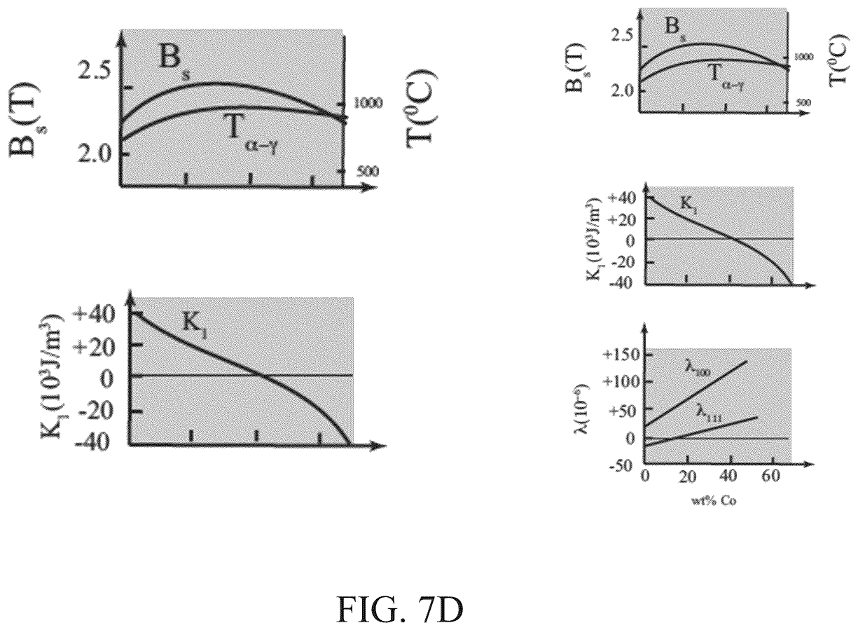

FIG. 7A shows images of 20 nm FeCo nanoparticles 702 and FeCo nanoparticles suspended in a paraffin matrix 704 in accordance with an embodiment of the present disclosure. In image 702 of FIG. 7A, Fe—Co nanoparticles are subjected to an external magnetic field, and in image 704, the samples are shown in a 5% dilution fixed in a paraffin matrix for the initial laboratory testing.

FIG. 7B is a diagram showing a comparison of the hysteresis curves for FeCo nanoparticles and commercially available ferrite material (Amidon Corp R61) in accordance with an embodiment of the present disclosure. The Fe—Co sample and ferrite-core were identically sized. The Fe—Co nanoparticles were nominally 19-nm in diameter and were tested in powder form. The data show that even in this non-ideal sample format, the Fe—Co sample shows twice the saturated magnetic field strength as the commercially available ferrite.

FIG. 7C shows diagrams illustrating the variation of the magnetization of Fe—Co and the anisotropy constant as a function of the x=Fe/Co ratio in accordance with an embodiment of the present disclosure. Notice that the value Bₛ is essentially constant with a small maximum of Bₛ=2.5 at x=3 larger than either elements Fe or Co. However, K has variation with a minimum of K lower than 1 kJ/m³ close to x=4 with extremely low coercivity.

FIG. 7D shows diagrams illustrating the variation of saturation magnetization, Tc, magnetocrystalline anisotropy, K1, and magnetostriction, λ, in FeCo alloys in accordance with an embodiment of the present disclosure. In an embodiment, in choosing a binary alloy composition in the binary Fe1-xCox system it is important to consider the maximum induction which occurs near x=0.3, the minimum magnetocrystalline anisotropy occurring near x=0.5, and finally compositions which minimize magnetostrictive coefficients. In the FeCo alloys magnetostriction coefficients, λ100 and λ111 are both substantial near the equiatomic composition where the magnetocrystalline anisotropy vanishes. Across this alloy system, Tc's are larger than Fe or Co). Consideration of alloy resistivity (important for determining eddy current losses) and alloy additions which influence mechanical properties

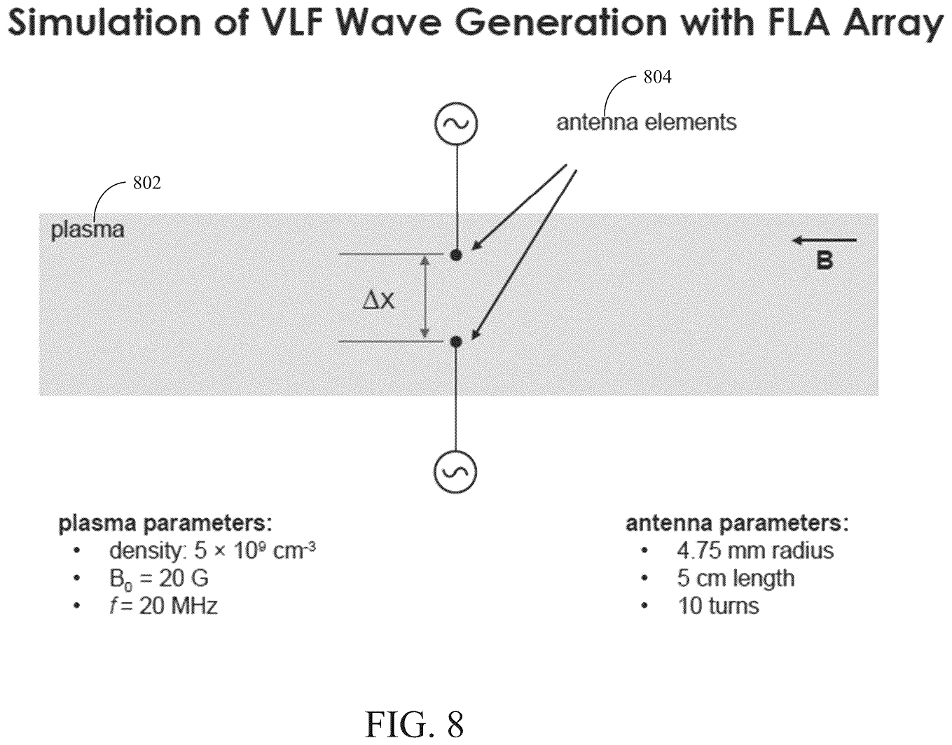

FIG. 8 shows a simulation of very low frequency (VLF) wave generation with a MANTA array in accordance with an embodiment of the present disclosure. FIG. 8 shows plasma 802 and antenna elements 804.

In a embodiment, MNT is a compact, low-power, single-domain magnetic nanoparticle antenna element that improves wave injection efficiency by more than 30 dB over conventional electric or magnetic dipoles. In an embodiment, MANTA can launch Electromagnetic Ion Cyclotron (EMIC) waves in space with sufficient amplitude to nonlinearly trigger emissions that lead to the scattering and removal of satellite-killing trapped radiation belt particles in the aftermath of a High-Altitude Nuclear Detonation (HAND) as well as extreme space weather. The antenna also has significant ELF/VLF signal transmission/reception applications. Laboratory experiments have demonstrated the increased EM wave amplitude and coupling efficiency of the antenna in simulated space plasma conditions.

MeV electrons generated in the aftermath of a HAND form long-lived artificial radiation belts with orders of magnitude greater flux than the natural belts can rapidly kill the LEO satellite fleet. Proposed mitigation techniques try to mimic natural radiation belt population control by electromagnetic (EM) plasma wave-induced particle scattering and loss. In a vapor release technique, photoionizable vapor release generates large levels of EM whistler waves, rapidly remediates trapped MeV electrons by whistler wave-induced particle scattering, and likely will not remediate 100% of MeV particles before wave generation ceases. MANTA complements this technique by attacking the remaining trapped particles.

In another technique, a USAF DSX satellite attempts to directly launch EM whistler waves using a large electric field dipole antenna, which is extremely inefficient due to poor coupling to the plasma caused by sheath effects. Deployment of 180-m antenna is complicated and requires many satellites to achieve remediation. MANTA avoids these losses by more efficient magnetic coupling to plasma.

In another technique, a USAF ParaLAX antenna uses a large magnetic loop antenna to launch EM whistler waves. The large size complicates deployment and low radiation resistance limits efficiency. MANTA dramatically increases radiation resistance with high-u nanoparticle cores.

Extremely Low Frequency (ELF) & Very Low Frequency (VLF) wave generation enable active control of dangerous trapped radiation belt particles (ELF & VLF) and undersea communications (VLF). Signals with frequency 10 Hz to 2 kHz propagate in the Earth-ionosphere waveguide. Due to their low frequency, they penetrate deep into sea water for communications with submerged submarines. They can be generated by Horizontal Electric Dipole (HED) but because the current closes through the conducting ground, the radiation is equivalent to that of a Horizontal Magnetic Dipole (HMD) with magnetic moment M=I ΔL. An array of scaled-up ground-based MANTA elements could be used to generate the required signal. Alternatively, a satellite constellation of space-based MANTA antennas could be used to directly pump the Earth-ionosphere waveguide.

In an embodiment, MANTA revolutionizes low-frequency wave transmission by improving the injection efficiency by more than 30 dB, while reducing size, weight & power. Two factors contribute to the MANTA efficiency increase over standard electric dipole and magnetic loop antennas: (1) high effective permeability of the core material; and (2) exploiting plasma physics. For (1), low-loss, high-permeability material within a multi-turn magnetic loop antenna increases the MANTA radiation resistance by a factor of μₑ², dramatically improving the coupling to the plasma and leads to lower required input current/voltage, lower heating, and reduced mass. For (2), additional gain is naturally achieved due to guidance of the EMIC wave (˜1-100 Hz) by the ambient magnetic field, confining the wave power to a cone smaller than 1°.

In an embodiment, MANTA provides seed Electromagnetic Ion Cyclotron (EMIC) waves that nonlinearly triggers an avalanche of EMIC wave emissions from the unstable trapped energetic proton populations. MANTA exploits the ubiquitous presence of trapped anisotropic stable energetic ions to nonlinearly destabilize them. This takes advantage of the free energy of the energetic ions to provide the necessary power for energetic electron remediation.

In an embodiment, MANTA uses a FeCo magnetic nanoparticle (MNP) antenna core, which has several advantages. For example, in an embodiment, the highest saturation magnetization Mₛ≈2.5 MA/m. This allows minimum weight for space applications. Use of a solid matrix prevents viscous losses and clumping that occurs in ferrofluids, while restricting the magnetic nanoparticle (MNP) response to the applied B in the low hysteresis flipping mode (Neal mode). Varying the mixing of Fc vs. Co allows control of the MNP inhomogeneity constant K. Minimizing K allows use of larger MNP volume and particle magnetic moment. This reduces the amplitude of the applied B₀ required to achieve saturation, thereby increasing the energy efficiency of the MNT array. Freezing the direction of the zero applied field MNP moment along the easy axis and techniques that control the distribution of the MNP size allows increase of the susceptibility value by factors 3-5. The 10-20% dilution of the MNT reduces the importance of the demagnetization by more than an order of magnitude over ferrites, allowing flexibility in the aspect ratio of the individual elements.

### 2. Exemplary Systems

Embodiments of the present disclosure provide a compact, low-power, high efficiency, low frequency transmitting antenna. In an embodiment, the MANTA is a low-power magnetic loop antenna that takes advantage of both the high gain from a high-permeability magnetic nanoparticle core and also an extremely narrow radiation pattern to launch low-frequency EMIC waves with amplitudes exceeding the TEMIC threshold at distances over several hundred kilometers.

Embodiments of the present disclosure provide a means for controlled direct interaction with energetic radiation belt particles trapped within Earth's magnetic field. The MNT includes an array of cylindrical magnetic nanoparticle cores with high permeability μ, each surrounded by a multiturn coil with N loops and driven by a matched AC circuit.

In an embodiment, the efficiency of a transmitting antenna is indicated by its radiation resistance. The radiation resistance of the MNT is given by:

$${R}_{r} ( {μ}_{e} , N , a , f ) = {μ}^{2} {N}^{2} {R}_{r} ( a , f ) \qquad ( 1 )$$

where Rᵣ=(1,1,a, f)˜(af⁴) is the free-space radiation resistance of a single-turn loop antenna. In Equation (1), a represents the radius of the core, and f is the frequency at which the antenna element is driven.

Equation (1) indicates that inserting a low-loss, high-u core in multi-turn coil increases its radiation resistance by a factor of μₑ₂. Note that the permeability μₑ is the value of the effective permeability that includes demagnetization effects, and is not the intrinsic permeability u of the core material. FIG. 2C illustrates the difference in radiation resistance between a vacuum/air-core antenna element and a high-u-core element.

Such antennas have primarily been used as receivers because in free space they provide essentially isotropic emission that is too inefficient for practical applications. However, this is not the case for launching waves in magnetized plasmas, especially in the EMIC frequency range, where the waves are naturally guided by the ambient magnetic field, providing an equivalent gain of more than 30 dB.

In an embodiment, a ferrite-core antenna array launches waves with significantly larger amplitudes, corresponding to the effective permeability, μₑ, of the ferrite material. While ferrite antennas do offer dramatic improvement to the operation of a magnetic loop antenna, there are several key drawbacks for space applications, including hysteresis losses and coercivity, eddy currents, relatively low saturation magnetization (M<10₅ A/m), and they are brittle and a risk of breaking during the high-vibration launch period.

Embodiments of the present disclosure overcome these drawbacks and provide significantly larger μₑ than ferrites, by, for example, using Single Domain Nanoparticles (SDN). A key requirement of SDN nanoparticles is their size. Magnetic domains within materials typically have dimensions on the order of μm scale lengths. Nanoparticles with dimensions smaller than the typical grain size allow each particle to be a Single Domain Nanoparticle in which the magnetization is a single giant moment, the sum of the magnetic moments of its constituent atoms.

Because of its magnetic anisotropy, the magnetic moment of each SDM has only two orientations antiparallel to each other separated by an energy barrier. This is known as the two-state (up and down) approximation. The stable orientations are known as the “easy axis” of SDN. In the absence of an applied magnetic field the magnetization of a sample composed of SDNs is zero. It is like a paramagnetic gas whose elements are composed of several thousand Bohr magnetons (μ_{B}). In an embodiment, the behavior of an ensemble of SDNs driven by an external magnetic field is controlled by the anisotropy constant K (J/m₃) and saturation magnetization Ms (A/m) or equivalently induction Bₛ(T) of the material and the SDN volume V. The barrier between the up and down states is given by E_{B}=KV, while the magnetic moment of the SDN by μ=MsV. The values of K and Mₛ also define the coercivity since the critical magnetic field Be, the equivalent field that constrains the SDN moment along the “easy axis” is given by B_{c}=2K/μ₀Mₛ.

Another important issue in using SDNs for MNT applications is the relaxation time, the time that it takes the SDN to return to its zero-magnetization equilibrium state after a magnetic pulse with field amplitude Bₒ is applied in one direction. At finite temperature, there is a probability that the particle will reverse direction. The mean time between two flips is called the Neel time and given by τ_{N}=τₒ exp(KV/k_{B}T), where to, known as “attempt time”, is a function of the material, and is typically of the order of nanosecond. In an embodiment, the applicability of an SDN core to MNT applications depends on the response of the magnetization driven by an external AC field B(t)=Bₒ cos(2πft) depends on the value of 2πτ_{N}, that for a given material and desired frequency depends on the particle volume. This allows us to define a critical volume V_{c}(f,K)=(k_{B}T/K)[1/ln(1/2πfτₒ)]. For room temperature and the frequencies of interest 0.01-1 kHz the critical volume is approximately:

$${V}_{c} ( K ) \approx 1 {0}^{4} ( \frac{kJ}{K} ) {nm}^{3} \qquad ( 2 )$$

For values of V>V_{c}, the magnetization will flip several times during an oscillation and will not respond to the AC field. This sets an upper limit on the volume V<V_{c}(f) for MNT applications to the frequencies of interest. An assembly of SDNs with V<V_{c}(f) has superparamagnetic behavior. The magnetization curve of an SPM subjected to an AC field is derived by statistical techniques like paramagnetic materials and is given by a reversible S curve. For a sample of SPMs with density n whose easy axis is aligned along the applied AC the magnetization M and susceptibility χ are given by:

$$M ( \frac{μ {B}_{o}}{{k}_{B} T} ) = n μ tanh ( \frac{μ {B}_{o}}{{k}_{B} T} ) , χ = \frac{n {μ}_{o} {μ}^{2}}{{k}_{B} T} \qquad ( 3 )$$

If the easy axis is randomly oriented with respect of the applied field M and χ are given by:

$$M ( \frac{μ {B}_{o}}{{k}_{B} T} ) = n μ L ( \frac{μ {B}_{o}}{{k}_{B} T} ) , χ = \frac{n {μ}_{o} {μ}^{2}}{3 {k}_{B} T} \qquad ( 4 )$$

where L(x)=1 tanh (x)−1x, is the Langevin function.

The analysis shows that the magnetic material properties required to optimize MNT performance is a large value of Mₛ combined with a small value of K. The energy requirement because the value of the barrier associated with the two states, given by E_{B}=KV, increases with value of K latter affects the energy barrier and enters exponentially in the value of τ_{N} that determines the hysteresis losses. While the susceptibility and magnetization increase with value of nanoparticle V, superparamagnetic behavior requires small V<V_{c} and V_{c}˜1/K.

Embodiments of the present disclosure rely on a Fe—Co alloy rather than elemental soft ferromagnets such as Fe (Bₛ=2.1 T, K=40 kJ/m3, Bk=50 mT) or Co (Bs=1.7 T, K=40 kJ/m3, Bk=45 mT). In an embodiment, the values of the magnetization and of the anisotropy of the Fe—Co alloy are a function of x=Co/Fe weight composition. Notice that while the Bs remains very large over the entire composition range and in fact has a maximum of Bs=2.5 T at x=0.3 that exceeds the induction value of either Fe or Co. Further, K varies between 40 kJ/m3 and −40 kJ/m3 and has a minimum near the equal weight x=0.5 ratio with value in the range few kJ/m3.

In an embodiment, when formed into a Fe—Co alloy with the desired mixture ratio and to act as a collection of independent nanomagnets, the Fe—Co nanoparticles are prevented from agglomerating under attractive magnetic forces and Van Der Waals forces by the addition of a particle coating. In an embodiment, the nanoparticles are then inserted in an elongated tube filled with nonconducting material, such as epoxy and uniformly dispersed. In an embodiment, to prevent demagnetization effects when the core is driven by the current of the surrounding multiloop care, the tube has a very large length-to-diameter ratio. To ensure that the ensemble of particles remains non-interacting, the mixture can be held to a 10-20% concentration.

We consider here a design example of a Fe—Co MNT element operating at room temperature, with a 50%-50% Fe—Co mixture. In an embodiment, the core has anisotropy constant K=5 kJ/m3, and saturation magnetization Ms=2×10⁶ A/m that is diluted to 10% volume ratio to avoid mutual interaction among the nanoparticles, will have relaxation time and magnetic moment m given by

$${τ}_{N} = \frac{0.12}{\sqrt{V / {V}_{o}}} {e}^{V / {V}_{o}} μ sec and m 4.5 \times {10}^{- 18} ( \frac{V}{{V}_{o}} ) A - {m}^{2} \qquad ( 5 )$$

Here, the volume V of a nanoparticle is in units of 10⁻²⁴ m³ and V₀=3×10⁻²⁴ m³ (18 nm diameter). For a magnetic nanoparticle sample with dilution factor α, the real and imaginary parts of the magnetic susceptibility will be given by:

$$r e ( μ ( f ) ) = \frac{an {μ}_{o} {mM}_{s} V}{{k}_{B} T} and im ( u ( f ) ) = 2 π f {τ}_{N} ( \frac{α n {μ}_{o} {mM}_{s} V}{{k}_{B} T} ) \qquad ( 6 )$$

Thus, for V/V₀=1, α=0.1 and f=120 Hz, we find μᵣₑₐₗ=450 and μ_{imag}=0.01. The demagnetization factor is smaller than that for a ferrite-core antenna of the same geometrical dimensions by the dilution factor α. As a result, an MNT containing 10% Fe—Co with a radius r=2 cm and length 1=30 cm will have μ_{eff}≈450 while maintaining a number of loops in the coil, N=150, by using 12 AGW wire with 2-mm radius.

Using these parameters to calculate the radiation resistance of the MNT, we find that for f=120 Hz, R_{MNT}=1Ω. Thus, injecting 1 W will require average current of 1 A. The value of Rᵣₑₛ will remain the same as for the ferrite-core antenna, Rᵣₑₛ=0.1Ω, while the Rhys will increase to 0.3Ω. The radiation efficiency factor will increase to k=0.7 and the total power requirement 1.4 W. Most importantly for space-based injection the total weight of such an antenna would be ˜0.6 kg, 50% the weight of insulating matrix and 50% of the Fe—Co. This, along with the greater power efficiency, can be critical for higher power injection. Furthermore, it can be accomplished with a nanosatellite or use of a combination of antennas to increase the radiated power.

Fe—Co nanoparticles with the desired diameter and composition can be prepared via a variety of methods. For proof of concept experiments, nanoparticles have been prepared via both the polyol method and via a hydrothermal decomposition. In each case, we have demonstrated the ability to prepare ˜1 g of Fe—Co nanoparticles per reaction at laboratory scale.

Polyol Reduction: Sodium hydroxide (52.98 g, 1.323 mol) was dissolved in dry and degassed ethylene glycol (400 mL) with gentle heating and stirring. A separate solution of FeCl₂ (5.59 g, 28.12 mmol) and Co(OAc)₂ (6.76 g, 27.15 mmol) was prepared in 100 mL of degassed ethylene glycol. Once all solids were dissolved, the iron and cobalt containing solution was injected to the NaOH solution and the color changed from clear to green, followed by a transition to dark purple/black. The solution was brought to reflux and allowed to heat for 45 minutes, at which point it was allowed to cool to room temperature naturally. The solution was diluted with MeOH, and the formed nanoparticles were trapped to the bottom of the flask with a magnet while the remaining solution decanted away. The collected powders were washed 5× with MeOH, or until the supernatant is clear. The collected solids were dried at 50° C. in air overnight.

Hydrothermal Reduction: In a typical synthesis process, 2.752 g of polyethylene glycol (PEG-800), 0.417 g of FeSO₄·7H₂O, 0.119 g of CoCl₂·6H₂O and 0.32 ml cyclohexane (C₆H₁₂) were dissolved in 20 ml doubly distilled water and the mixture was magnetically stirred vigorously for 30 min. The obtained pink solution was heated to 80° C. in a water bath and a separate solution of 0.988 g of sodium hydroxide (NaOH) and 8.5 ml of 80 wt % hydrazine was prepared. The NaOH/Hydrazine mixture was quickly dropped into the preheated Fe and Co salt solution at which point the color of the pink solution turned black from blue. Then the combined solution was transferred into a 50 ml Teflon-lined cup in a stainless-steel autoclave. The autoclave was heated at 160° C. for 3 h and then air-cooled to room temperature. After reaction, the solutions became colorless and transparent with a black feathery solid product deposited on the bottom of the Teflon-lined cup. The product was separated using a permanent magnet bar and washed with doubly distilled water 5 times and with ethyl alcohol 3 times. These clean particles were dried in a vacuum oven for 10-24 h at room temperature.

The prepared nanoparticles are then encased in a polymer matrix. To date we have demonstrated the ability to use both low melting paraffin wax, as well as a polyurethane; however, other matrices such as epoxy resin can be utilized. The amount of Fe—Co included in the composite can be varied from 0-90% by mass.

FIG. 6 shows a photograph of a sample of the 19-nm NRL Fe—Co nanoparticles subjected to an external magnetic field. FIG. 7A shows the samples in a 5% dilution fixed in a paraffin matrix for the initial laboratory testing. In ferrofluid form, the magnetic nanoparticles are suspended in solutions. When subjected to an externally imposed magnetic field, each of the magnetic nanoparticles can align their magnetic moments with the external field by either flipping their moments or by physical rotation of the entire nanoparticle within the solution. Physical rotation of the nanoparticle leads to viscous losses, particularly in the case where the driving field is oscillatory. Such losses are unacceptable for application as a transmitting antenna. Consequently, the magnetic nanoparticles for the MNT cores much be rigidly held in place in a solid-core matrix.

In an embodiment, the Fe—Co nanoparticles for the MNT core are held fixed by an epoxy binder, with magnetic moments aligned by imposing a background axial magnetic field during the epoxy curing process. For laboratory testing during the development phase, the Fe—Co nanoparticles were first tested in a paraffin core.

In an embodiment, to disperse the Fe—Co nanoparticles in a paraffin matrix, the appropriate amount of Fe—Co nanoparticles and paraffin wax was measured. The wax was melted via a warm water bath, and the tip of a horn sonicator was inserted. The Fe—Co powder was added to the melted wax, and ultrasonically dispersed for 5 minutes. The Fe—Co/wax composite is then poured into the appropriate mold, and rapidly cooled to solidify the matrix.

To prepare Fe—Co composites in polyurethane, commonly utilized ingredients and methods were utilized. An example mixing, casting, and curing procedure for a 25 wt % Fe—Co composite is as follows. A 10-gram batch of composite was prepared by mixing R45M (6.8 g) and triphenyl bismouth (0.02 g) until dissolved. At this point Fe—Co powder (2.5 g) was added and the sample mixed in a FlackTec SpeedMixer (DAC 1200-300 VAC) and mixed at 1000 rpm for 2 minutes.

After the Fe—Co powder was fully dispersed isophorone diisocyanate (IPDI, 0.7 g) was added and the resin mixed again. The second mixing was carried out in two distinct steps (1) ambient pressure, 1000 rpm, 2 minutes followed directly by (2) vacuum, 1000 rpm 3 minutes for a total of 5 minutes of mixing time. At this point the resin was fully mixed and degassed and poured into the appropriate molds. The composites were cured at 65° C. for 72 hours and held at room temperature for another 48 hours to ensure complete curing before testing. In an embodiment, the Fe—Co sample shows twice the saturated magnetic field strength as the commercially available ferrite. When the Fe—Co particles are arranged in the large aspect ratio cylindrical solid matrix core, the performance is expected to improve substantially.

### 3. Exemplary Antennas and Arrays

Embodiments of the present disclosure provide antennas with nanoparticle cores specifically engineered for a certain kind of performance, and they can be used in an array to drive interactions in plasma. In an embodiment, the core is made of tons of nanoparticles made out of FeCo made small enough so that they are considered single domain so that all atoms line up the right way. In an embodiment, a cap over the nanoparticles maintains separation between them so that they act independently. In an embodiment, the cap is a polymer cap, and the geometry of the core has a large aspect ratio-long and skinny (e.g., length to radius ratios of about 20).

In an embodiment, the coil has as many windings as possible without driving inductance too high (e.g., it is undesirable for impedance when driven with AC voltages to get too high; instead, drive largest amplitude with lowest input power). In an embodiment, the antennas and arrays are intended for use in space, so size, weight, and power efficiency is important. In an embodiment, the FeCo nanoparticle core has high magnetic moment so it's a multiplier of the magnetic field that the coil produces. In an embodiment, single domain nanoparticles can react very quickly to a changing signal so that hysteresis or demagnetization loses can be avoided. In an embodiment, the coil material is copper wire (or gold).

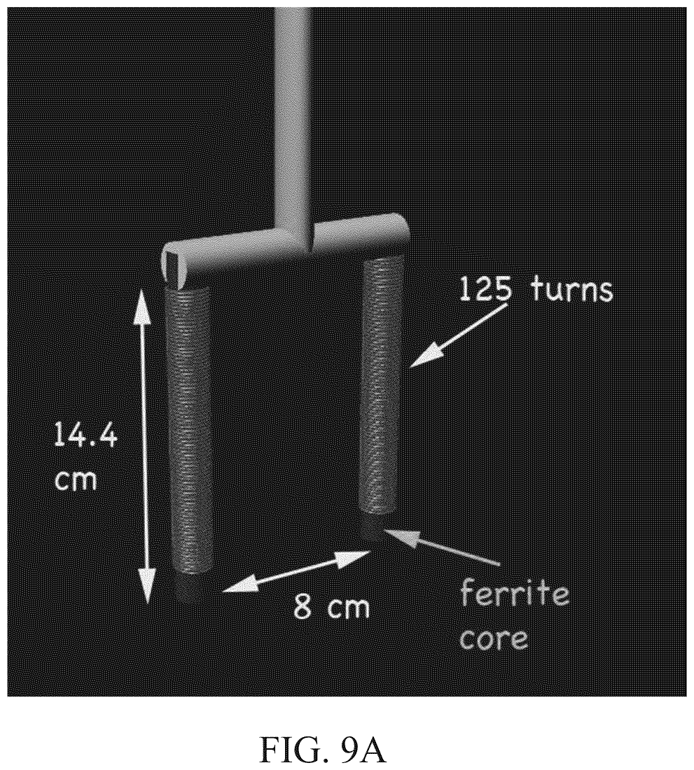

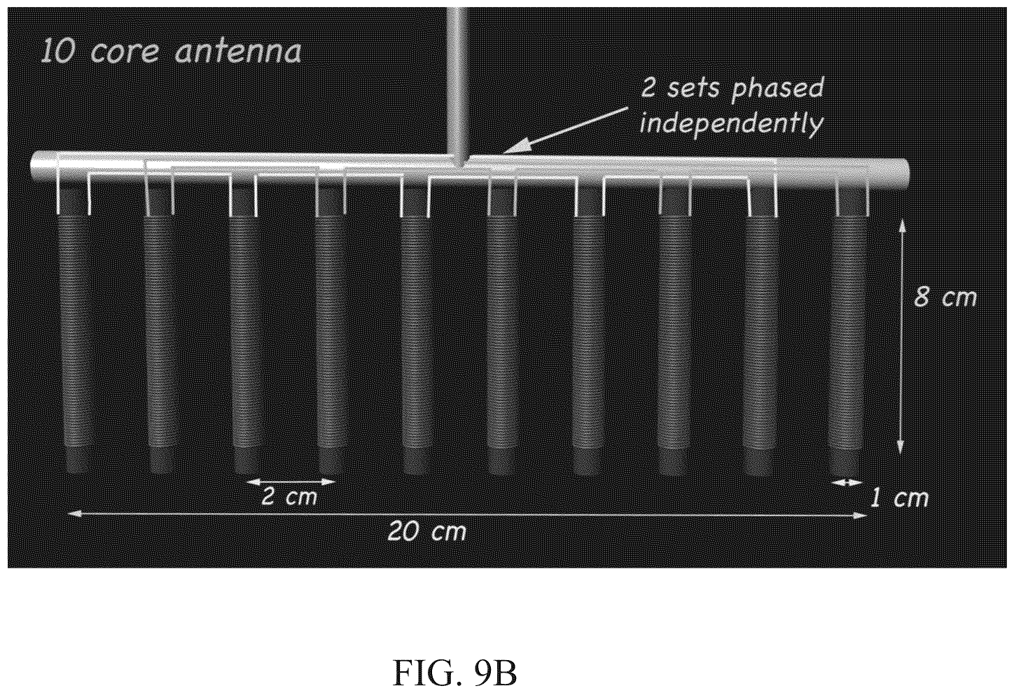

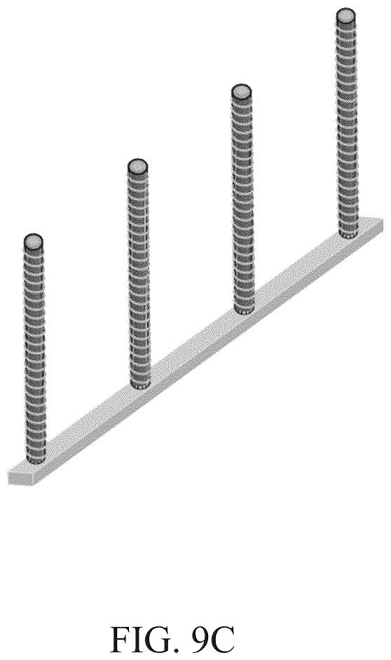

FIG. 9A is a diagram showing an exemplary linear array configuration with two antenna cores in accordance with an embodiment of the present disclosure. In the configuration of FIG. 9A, the waves being driven have wavelength going along Earth's magnetic field, and adding more elements in the array provides more repetitions of wavelength or resolution, driven with a particular phase between them to shape the wave being driven. FIG. 9B is a diagram showing an exemplary linear array configuration with 10 antenna cores in accordance with an embodiment of the present disclosure. FIG. 9C is a diagram showing an exemplary linear array configuration with 4 antenna cores in accordance with an embodiment of the present disclosure.

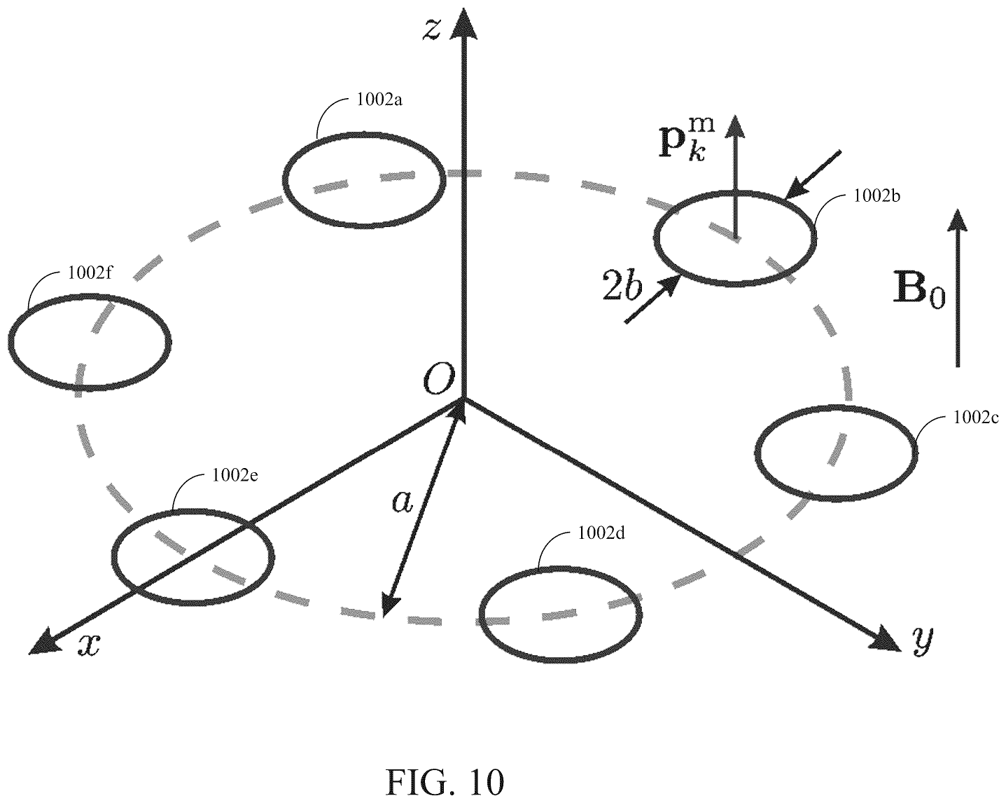

FIG. 10 is a diagram showing an exemplary circular array configuration in accordance with an embodiment of the present disclosure. In FIG. 10, each circle represents a manta element 1002 facing up and down, (e.g., in an embodiment the same linear elements shown in FIGS. 9A and 9B but arranged in a circle). In FIG. 10, elements 1002 are driven with particular phase to get rotation around the circle. In an embodiment, the circular pattern enhances resonance with particles in the ionosphere that helps to remove dangerous particles.

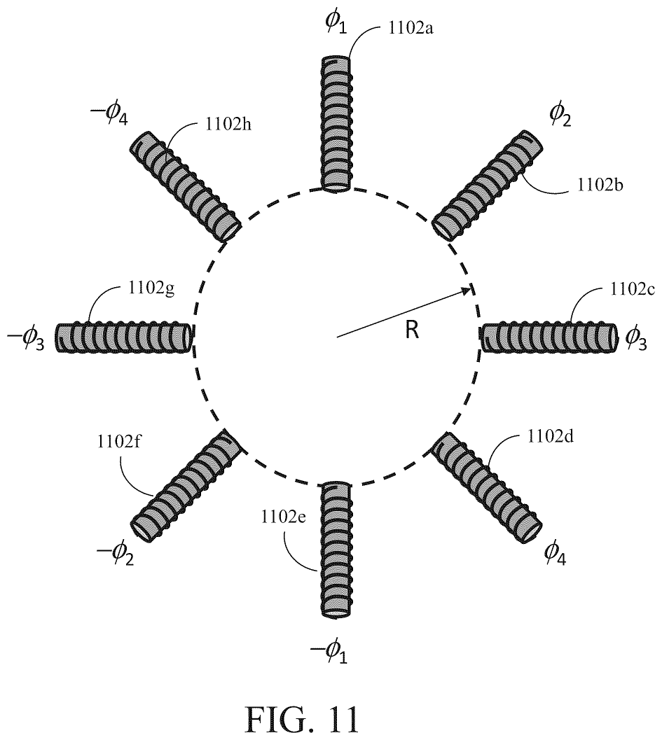

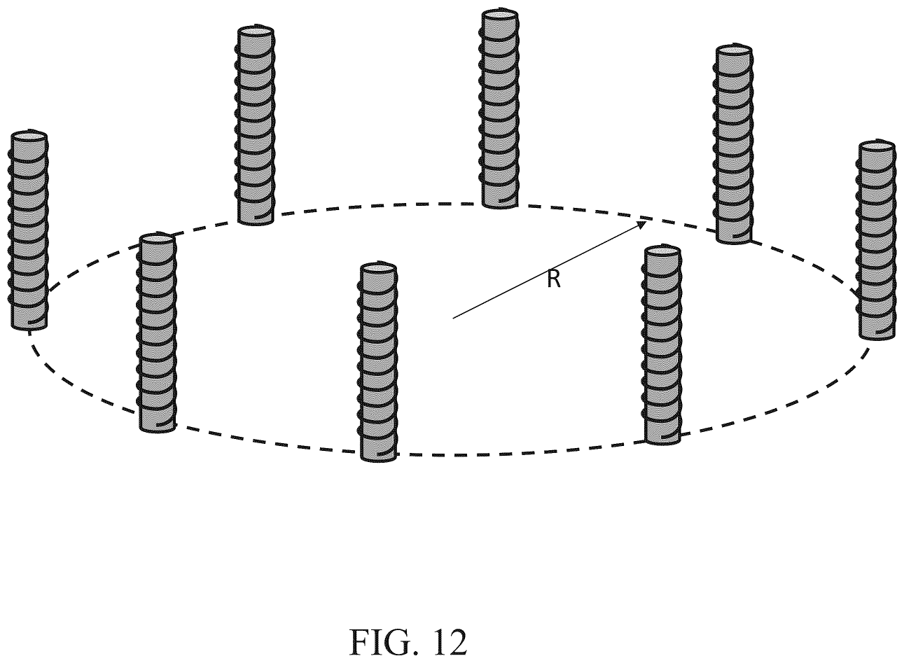

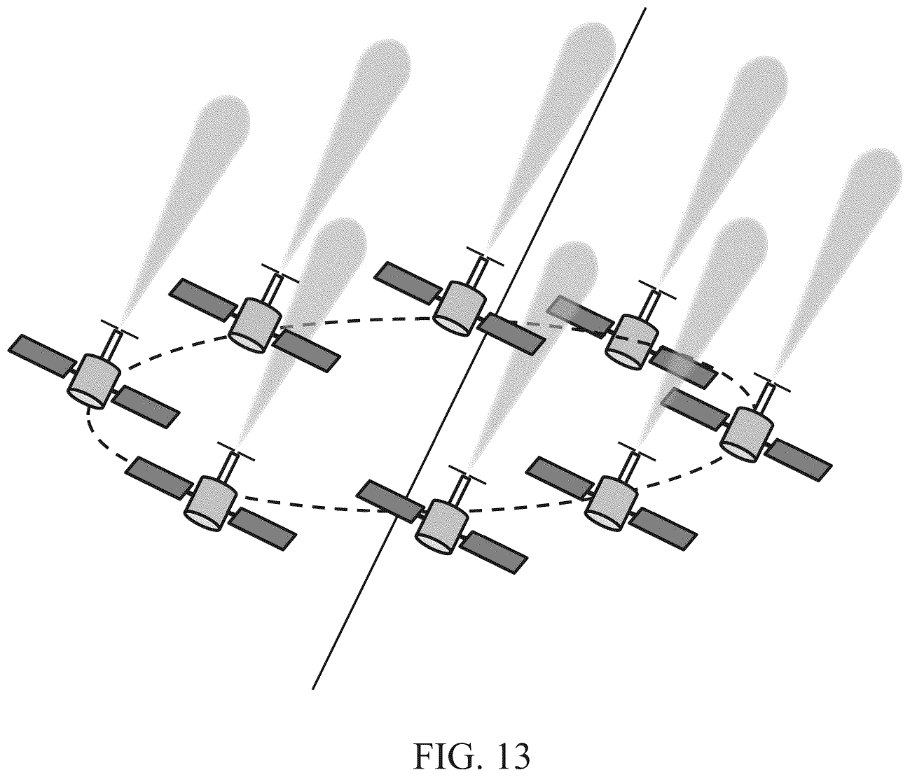

FIG. 11 is a diagram showing another exemplary circular array configuration in accordance with an embodiment of the present disclosure. In FIG. 11, elements 1102 are oriented horizontally rather than vertically as shown in FIG. 10. FIG. 12 is a diagram showing another exemplary circular array configuration in accordance with an embodiment of the present disclosure. FIG. 13 is a diagram showing another exemplary circular array configuration of satellites with phased MANTA transmitting antennas in accordance with an embodiment of the present disclosure. In an embodiment, the interaction of individual phased MANTA radiated waves results in maximized power and controlled size to the targeted area.

A circular arrays of N MANTA elements can be used to drive plasma oscillations at the driver frequency. In an embodiment, element angular spacing and driver phasing to each element controls azimuthal wavelength of the wave. Waves can be driven with right-hand circular polarization for electromagnetic whistler waves. Waves can be driven with left-hand circular polarization for electromagnetic ion cyclotron waves. In an embodiment, circular arrays can be used for driving waves with orbital angular momentum (OAM) necessary for resonance with trapped energetic radiation belt electrons and efficient wave-particle interactions. In an embodiment, the OAM modifies a Larmor radius of relativistic electrons leading to a breakdown of adiabatic invariants, thereby causing them to precipitate.

In an embodiment, a MANTA array can include multiple circular arrays. In an embodiment, these multiple circular arrays can be oriented in a stacked configuration. For example, in an embodiment, the circular array configuration of FIG. 10 can be a first layer of the stack, and another circular array configuration of elements can be positioned above this first layer.

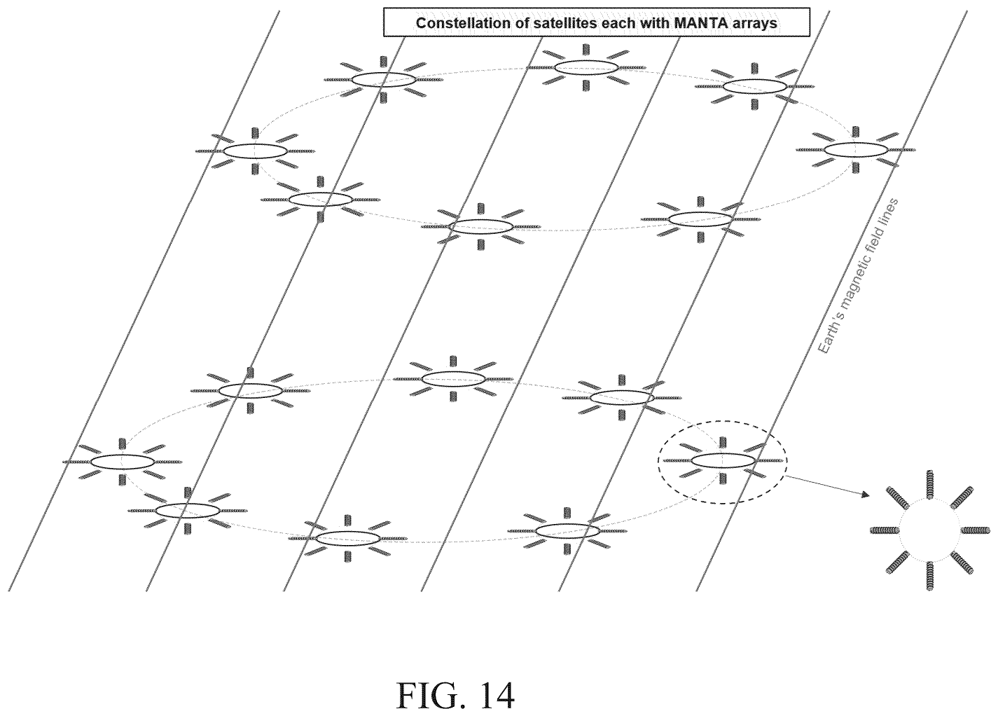

FIG. 14 is a diagram showing a constellation of satellites, each fielding a manta array, in accordance with an embodiment of the present disclosure. By controlling the size and separation of the satellites and the phasing of the arrays, plasma wave structures can be optimized for resonant interaction with energetic trapped radiation belt particles can be produced.

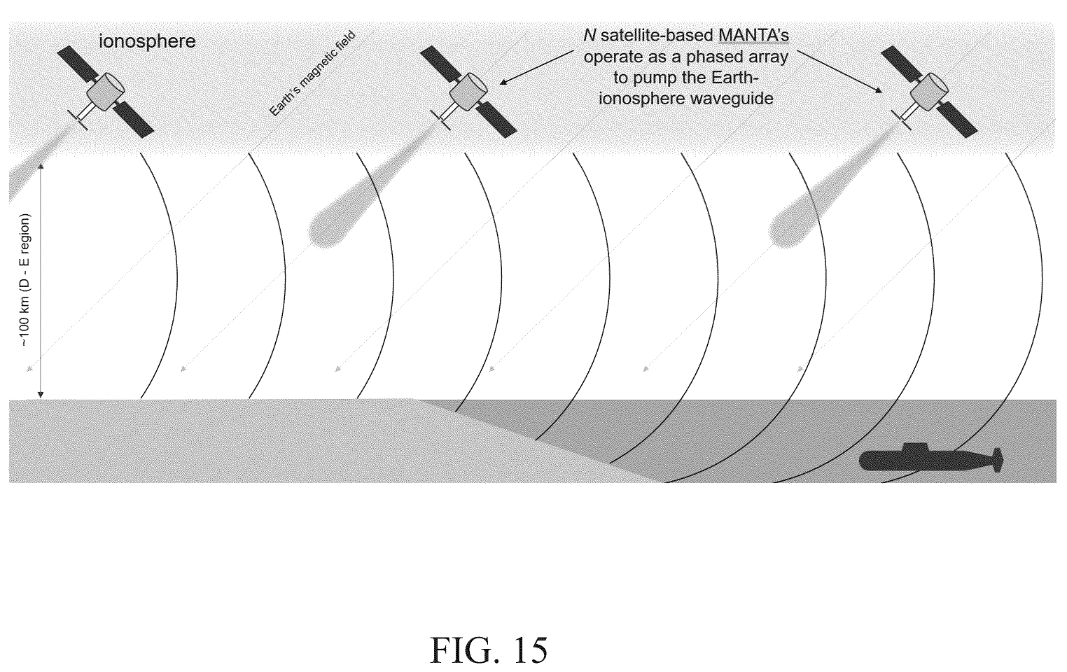

As discussed above, MANTA arrays can also be used for ground-based VLF wave generation. For example, a 2d phased array can be built of larger-scale MANTA elements for directional launching of VLF waves (300 Hz-30 kHz) for undersea communications. Such an exemplary 2D phased array is shown in FIG. 4A. FIG. 15 is a diagram showing exemplary very low frequency (VLF) communications via satellite constellations of MANTA arrays in accordance with an embodiment of the present disclosure. In FIG. 15, N satellite-based MANTA arrays can operate as a phased array to pump the Earth-ionosphere waveguide.

### 4. Exemplary Alternatives

In an embodiment, linear arrays in the transverse and longitudinal directions can be utilized to selectively pump specific mode wavenumbers to drive waves with the desired properties. MNT elements arranged in circular arrays with selectable radius can be used to drive modes with specific left- or right-handed polarization while the radius of the array controls the radial wavenumber of the mode. In an embodiment, several circular arrays can be stacked creating three-dimensional arrays. In an embodiment, arrays placed in groups of satellites can be phased to interfere to inject magnetic configurations with the desired dimensions and amplitudes.

Thus, as described herein, embodiments of the present disclosure provide an apparatus that can launch (and detect) ELF/VLF electromagnetic waves in plasmas and also in free space. Although particular embodiments, aspects, and features have been described and illustrated, one skilled in the art would readily appreciate that the invention described herein is not limited to only those embodiments, aspects, and features but also contemplates any and all modifications and alternative embodiments that are within the spirit and scope of the underlying invention described and claimed herein. The present application contemplates any and all modifications within the spirit and scope of the underlying invention described and claimed herein, and all such modifications and alternative embodiments are deemed to be within the scope and spirit of the present disclosure.

### 5. Conclusion

It is to be appreciated that the Detailed Description, and not the Abstract, is intended to be used to interpret the claims. The Abstract may set forth one or more but not all exemplary embodiments of the present disclosure as contemplated by the inventor(s), and thus, is not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

While various embodiments of the present disclosure have been described above, it should be understood that they have been presented by way of example only, and not limitation. It will be apparent to persons skilled in the relevant art that various changes in form and detail can be made therein without departing from the spirit and scope of the disclosure. Thus, the breadth and scope of the present disclosure should not be limited by any of the above-described exemplary embodiments.

What is claimed is:

1. A magnetic nanoparticle (MNT) antenna, comprising:
a cylindrical core comprising a plurality of FeCo magnetic nanoparticles; and
a wire coil wrapped around the cylindrical core.

2. The MNT antenna of claim 1, further comprising:
an alternating current (AC) circuit coupled to the wire coil, wherein the AC circuit is matched to the wire coil, and wherein the AC circuit is configured to drive the wire coil.

3. The MNT antenna of claim 1, wherein the wire coil is a solenoidal wire coil.

4. The MNT antenna of claim 1, wherein the radiation resistance of the MNT antenna is given by Rᵣ(μₑ, N, a, f)=μ²N²Rᵣ(a, f), wherein Rᵣ=(1, 1, a, f)˜(af⁴) is the free-space radiation resistance of a single-turn loop antenna, wherein u is the permeability of the core, μe is a value of an effective permeability that includes demagnetization effects, N represents a number of loops in the wire coil, a represents a radius of the core, and f represents of frequency of the MNT antenna.

5. The MNT antenna of claim 1, wherein the FeCo magnetic nanoparticles are Single Domain Nanoparticles (SDN) nanoparticles.

6. The MNT antenna of claim 1, wherein each nanoparticle in the plurality of FeCo magnetic nanoparticles is a single domain nanoparticle (SDN).

7. The MNT antenna of claim 6, wherein a magnetization of each SDN is a single moment, and wherein the single moment is a sum of a plurality of magnetic moments of constituent atoms of each SDN.

8. The MNT antenna of claim 6, wherein a magnetic moment of each SDM has only two orientations antiparallel to each other separated by an energy barrier.

9. The MNT antenna of claim 1, further comprising:
a polymer cap covering the FeCo magnetic nanoparticles, wherein the polymer cap maintains a separation between the FeCo magnetic nanoparticles such that the FeCo magnetic nanoparticles act independently.

10. The MNT antenna of claim 1, wherein the cylindrical core has a length to radius ratio of approximately 20.

11. The MNT antenna of claim 1, wherein the wire coil is made from copper.

12. An antenna, comprising:
a base comprising an alternating current (AC) circuit;
a first magnetic nanoparticle (MNT) antenna element coupled to the base, wherein the first MNT element comprises:
a cylindrical core comprising a plurality of FeCo magnetic nanoparticles, and
a wire coil wrapped around the cylindrical core, wherein the wire coil is matched to the AC circuit, and wherein the AC circuit is configured to drive the wire coil;
a second MNT antenna element coupled to the base, wherein the second MNT antenna element is positioned at a 90 degree angle from the first MNT element;
a third MNT antenna element coupled to the base, wherein the third MNT antenna element is positioned at a 90 degree angle from the second MNT element; and
a fourth MNT antenna element coupled to the base, wherein the fourth MNT antenna element is positioned at a 90 degree angle from the third MNT element and the first MNT element.

13. The MNT antenna of claim 12, wherein the plurality of MNT elements are oriented horizontally with respect to the base.

14. The antenna of claim 12, wherein the plurality of MNT elements are configured in a crossed dipole configuration.

15. The MNT antenna of claim 12, wherein the wire coil is a solenoidal wire coil.

16. The MNT antenna of claim 12, wherein the FeCo magnetic nanoparticles are Single Domain Nanoparticles (SDN) nanoparticles.

17. The antenna of claim 12, wherein each nanoparticle in the plurality of FeCo magnetic nanoparticles is a single domain nanoparticle (SDN).

18. The MNT antenna of claim 12, further comprising:
a polymer cap covering the FeCo magnetic nanoparticles, wherein the polymer cap maintains a separation between the FeCo magnetic nanoparticles such that the FeCo magnetic nanoparticles act independently.

19. The MNT antenna of claim 12, wherein the cylindrical core has a length to radius ratio of approximately 20.

20. A magnetic nanoparticle (MNT) antenna, comprising:
a cylindrical core having a length to radius ratio of approximately 20, the cylindrical core comprising:
a plurality of FeCo Single Domain Nanoparticles (SDN), wherein a magnetization of each SDN is a single moment, wherein the single moment is a sum of a plurality of magnetic moments of constituent atoms of each SDN, and wherein a magnetic moment of each SDN has only two orientations antiparallel to each other separated by an energy barrier, and
a polymer cap covering the SDN, wherein the polymer cap maintains a separation between the SDN such that the SDN act independently;
a solenoidal wire coil wrapped around the cylindrical core; and
an alternating current (AC) circuit coupled to the wire coil, wherein the AC circuit is matched to the wire coil, and wherein the AC circuit is configured to drive the wire coil.
